(19) United States
(12) Patent Application Publication
(10) Pub. No.: US 2011/0294992 A1
(43) Pub. Date: Dec. 1, 2011

(54) METAL RESPONSIVE MRI-AGENTS

(75) Inventor: Christopher J. CHANG, Berkeley, CA (US)

(73) Assignee: The Regents of the University of California, Oakland, CA (US)

(21) Appl. No.: 13/151,028

(22) Filed: Jun. 1, 2011

Related U.S. Application Data
(60) Provisional application No. 61/350,356, filed on Jun. 1, 2010.

(51) Int. Cl. C07F 5/00; G01R 33/48

(52) U.S. Cl. 534/16; 324/309

(57) ABSTRACT

The present invention provides compositions comprising an MRI contrast agent and methods of their use.

### CROSS-REFERENCE TO RELATED APPLICATIONS

This application claims under 35 USC 119(e) the benefit of U.S. Application 61/350,356, filed Jun. 1, 2010, which is incorporated by reference in its entirety.

### STATEMENT OF GOVERNMENT SUPPORT

This work was supported by a grant from the National Institute of Health (GM 079465). The Government has certain rights in this invention.

### BACKGROUND OF THE INVENTION

Copper is an essential element for life¹⁻⁷ owing in large part to its ability to cycle between multiple oxidation states. At the same time, this redox reactivity is potentially harmful to living organisms, as compromises in homeostatic control of copper pools can result in oxidative stress and subsequent damage to tissue and organ systems.⁸⁻¹⁶ Understanding this dual nature of biological copper has led to our interest in developing new ways to study aspects of copper ion accumulation, trafficking, and export in living systems by molecular imaging, particularly in both its major oxidation states, Cu⁺ and Cu²⁺.¹⁷⁻²¹

A well-suited technique to this end is magnetic resonance imaging (MRI), a modality that allows non-invasive, three-dimensional visualization of whole organisms with spatial and temporal resolution.²⁸⁻³⁵ In this context, paramagnetic metal ions, such as Gd³⁺ (S=7/2), can enhance proton MR signal contrast by increasing the relaxation rates of the protons in water molecules interacting with the metal center. The efficiency with which a contrast agent can enhance these rates is called relaxivity (r₁). Relaxivity values are governed by a variety of factors according to Solomon-Bloembergen-Morgan theory³⁶⁻³⁸ including the number of bound water molecules (q), the rotational correlation time (τ_{R}), and the mean residence lifetime of Gd³⁺-bound water molecules (τ_{M}).

As conventional MRI contrast agents exhibit constant r₁ relaxivity values at a given field, we sought to create complexes that would change their r₁ in response to Cu⁺ and/or Cu²⁺ ions for use as chemosensors. Meade first pioneered this “smart” MRI contrast agent approach to detect β-galactosidase activity,³⁹ and several examples of contrast agents that respond to enzymatic activity,³⁹⁻⁵¹ pH,⁵²⁻⁵⁸ glucose,^{59,60} lactate,⁶¹ nitric oxide,⁶² Ca²⁺,⁶³⁻⁶⁹ Zn²⁺,⁷⁰⁻⁷⁵ and K⁺⁷⁶ have also been described. We recently reported the synthesis and properties of Copper-Gad-1 (CG1),¹⁹ the first copper-activated MR sensor. This initial design was capable of sensing changes in Cu²⁺ levels in aqueous solution with good selectivity over abundant cellular cations, but exhibited a modest turn-on change (41% increase) that was partially muted in the presence of 10-fold excess Zn²⁺. We now present the development of a next-generation family of CG sensors (FIG. 1) with greatly improved specificity for Cu⁺ and/or Cu²⁺ ions, particularly over large excesses of Zn²⁺, with turn-on relaxivity changes up to 360%. The introduction of thioether-based donors provides a practical strategy for discriminating copper versus zinc ions.^{77,78} Included in FIG. 2 are CG contrast agents containing copper-binding groups with varied donor atoms (N, S, O) and denticities (3, 4, 5). The copper-induced turn-on responses, binding properties, and metal ion selectivities of these new CG agents have been investigated using T₁ measurements at 60 MHz. A combination of nuclear magnetic relaxation dispersion (NMRD) and Dy³⁺-induced ¹⁷O shift (DIS) experiments are consistent with MR-based copper sensing through q modulation. Finally, T₁-weighted phantom images establish that the CG sensors are capable of visualizing changes in copper levels by MRI at clinical field strengths, providing a basis for the potential use of these agents for copper-targeted MRI.

### SUMMARY OF INVENTION

Disclosed herein are composition and methods useful for detecting analytes. In exemplary embodiments, the compositions described herein can be used to generate signals that are distinguishable using MRI techniques. The invention provides both compositions that are “turned off” because of the absence of analyte and compositions that are “turned on” in the presence of analyte, in particular certain metal ions such as copper metal ions. In transitioning from the off to on state, the compositions, which generally comprise a first metal ion, will undergo a conformational change such that interactions between the first metal ion and surrounding molecules are modified. For example, the presence of analyte could cause the removal of a coordinate bond between a heteroatom and the first metal ion, thereby increasing the interactions between the first metal ion and the surrounding solvent.

Accordingly, in one aspect, the invention provides a composition comprising (a) a first chelator chelated to a first metal ion and (b) a second chelator covalently bound to the first chelator, wherein the second chelator is chelated to a second metal ion.

In one aspect, the invention provides a composition comprising (a) a first chelator chelated to a first metal ion and (b) a second chelator covalently bound to the first chelator, wherein the second chelator is chelated to a second metal ion.

In one aspect, the invention provides a method of assaying a sample comprising (a) contacting the sample with a composition disclosed herein; and (b) measuring an MRI signal produced by the sample.

### BRIEF DESCRIPTION OF DRAWINGS

FIG. 1. Design strategy for copper-activated MRI sensors.

FIG. 2. Thioether-based Copper-Gad (CG) contrast agent platforms.

FIG. 3. Relaxivity response of 0.2 mM CG2 to various concentrations of Cu⁺. Relaxivity measurements were acquired at 37° C. in 20 mM HEPES buffer, pH 7, at a proton Larmor frequency of 60 MHz.

FIG. 4. Job's plot of CG2 and Cu⁺. The total concentrations of CG2 and Cu⁺ were kept at a constant 0.2 mM Relaxivity measurements were acquired at 37° C. in 20 mM HEPES buffer, pH 7, at a proton Larmor frequency of 60 MHz. The maximum response at 0.5 mole fraction CG2 and Cu⁺ is consistent with formation of a 1:1 Cu⁺:CG2 complex.

FIG. 5. Normalized absorbance response of 0.2 mM CG2-6 to buffered Cu⁺ (CG2-5) or Cu²⁺ (CG6) solutions for K_{d} value determination. Spectra were acquired in 20 mM HEPES, pH 7. The black lines represent the best fit lines (R² values displayed below each data set).

FIG. 6. Relaxivity responses of CG2 to various metal ions. White bars represent the addition of an excess of the appropriate metal ion (10 mM for Na⁺, 2 mM for K⁺, Mg²⁺, and Ca²⁺, and 0.2 mM for Fe²⁺, Fe³⁺, Cu²⁺) to a 0.2 mM solution of CG2. Response to Zn²⁺ was measured both at 0.2 mM Zn²⁺ (Zn²⁺1×) and 2 mM Zn²⁺ (Zn²⁺10×). Black bars represent the subsequent addition of 0.2 mM Cu⁺ to the CG2 solution. Relaxivity measurements were acquired at 37° C. in 20 mM HEPES buffer, pH 7, at a proton Larmor frequency of 60 MHz.

FIG. 7. Relaxivity responses of CG2 to 1 equiv Cu⁺ in the presence of biologically relevant anions. White bars represent CG2 relaxivities without Cu⁺ in the presence of various anions. Black bars represent CG2 relaxivities with Cu⁺ in the presence of different anions. Percentages in the black bars are the % increases r₁. Relaxivity measurements with HEPES, citrate (0.13 mM), lactate (2.3 mM), and HCO₃⁻ (10 mM, 25 mM), were acquired at 37° C. in 20 mM HEPES buffer, pH 7, at a proton Larmor frequency of 60 MHz. Relaxivity measurements with PBS were acquired under similar conditions using phosphate buffered saline, pH 7.4.

FIG. 8. Plot of [DyCG2] vs. −Δ ppm of the ¹⁷O signal of H₂O in the absence and presence of 1 equiv Cu⁺. Spectra were acquired at room temperature in 20 mM HEPES buffer, pH 7, at a ¹⁷O Larmor frequency of 67.8 MHz.

FIG. 9. ¹H Nuclear magnetic relaxation dispersion profiles of CG3 and CG3+Cu⁺ acquired at 25° C. The solid lines represent the best fit profiles.

FIG. 10. A) T₁-weighted phantom images of 100 μM CG2-6 in 20 mM HEPES pH 7 with and without 1 equiv Cuⁿ⁺. B) Phantom images of 100 μM CG2-6 with 0, 10, 25, 50, 75, and 100 μM [Cu(NCCH₃)₄]PF₆. Images were acquired at 25° C. at 1.5 T (˜64 MHz proton Larmor frequency).

### DETAILED DESCRIPTION OF THE INVENTION

The present invention provides numerous MRI contrast agents and methods of their use.

### Definitions

The term “alkyl”, by itself or as part of another substituent, means a straight or branched chain hydrocarbon radical, which may be fully saturated, mono- or polyunsaturated. For convenience, the term alkyl may refer to divalent (i.e., alkylene) and other multivalent radicals in addition to monovalent radicals. Examples of saturated hydrocarbon radicals include groups such as methyl, ethyl, n-propyl, isopropyl, n-butyl, t-butyl, isobutyl, sec-butyl, cyclohexyl, (cyclohexyl)methyl, cyclopropylmethyl, homologs and isomers of, for example, n-pentyl, n-hexyl, n-heptyl, n-octyl and the like. An unsaturated alkyl group is one having one or more double bonds or triple bonds (i.e., alkenyl and alkynyl moieties). Examples of unsaturated alkyl groups include vinyl, 2-propenyl, crotyl, 2-isopentenyl, 2-(butadienyl), 2,4-pentadienyl, 3-(1,4-pentadienyl), ethynyl, 1- and 3-propynyl, 3-butynyl, and the higher homologs and isomers.

Typically, an alkyl (or alkylene) group will have from 1 to 30 carbon atoms, That is, in some embodiments, alkyl refers to an alkyl having a number of carbons selected from C₁, C₂, C₃, C₄, C₅, C₆, C₇, C₈, C₉, C₁₀, C₁₁, C₁₂, C₁₃, C₁₄, C₁₅, C₁₆, C₁₇, C₁₈, C₁₉, C₂₀, C₂₁, C₂₂, C₂₃, C₂₄, C₂₅, C₂₆, C₂₇, C₂₈, C₂₉, C₃₀ and any combination thereof. In some embodiments, alkyl refers to C₁-C₂₅ alkyl. In some embodiments, alkyl refers to C₁-C₂₀ alkyl. In some embodiments, alkyl refers to C₁-C₁₅ alkyl. In some embodiments, alkyl refers to C₁-C₁₀ alkyl. In some embodiments, alkyl refers to C₁-C₆ alkyl.

The term “heteroalkyl”, by itself or in combination with another term, means an alkyl in which at least one carbon is replaced with an atom other than carbon (i.e., a heteroatom). In some embodiments, the heteroatom is selected from O, N and S, wherein the nitrogen and sulfur atoms may optionally be oxidized and the nitrogen heteroatom may optionally be quaternized. In some embodiments, a heteroalkyl is any C₂-C₃₀ alkyl, C₂-C₂₅ alkyl, C₂-C₂₀ alkyl, C₂-C₁₅ alkyl, C₂-C₁₀ alkyl or C₂-C₆ alkyl in any of which one or more carbons are replaced by one or more heteroatoms selected from O, N and S. The heteroatoms O, N and S may be placed at any interior position of the heteroalkyl group and may also be the position at which the heteroalkyl group is attached to the remainder of the molecule. In some embodiments, depending on whether a heteroatom terminates a chain or is in an interior position, the heteroatom may be bonded to one or more H or C₁, C₂, C₃, C₄, C₅ or C₆ alkyl according to the valence of the heteroatom. Examples include —CH₂—CH₂—O—CH₃, —CH₂—CH₂—NH—CH₃, —CH₂—CH₂—N(CH₃)—CH₃, —CH₂—S—CH₂—CH₃, —CH₂—CH₂, —S(O)—CH₃, —CH₂—CH₂—S(O)₂—CH₃, —CH═CH—O—CH₃, —CH₂—CH═N—OCH₃, and —CH═CH—N(CH₃)—CH₃. Up to two heteroatoms may be consecutive, such as, for example, —CH₂—NH—OCH₃. The term “heteroalkylene” may be use to refer a divalent radical derived from heteroalkyl. Unless otherwise stated, no orientation of the linking group is implied by the direction in which a divalent group is written. For example, the formula —C(O)₂R′— represents both —C(O)₂R′— and —R′C(O)₂—.

The terms “cycloalkyl” and “heterocycloalkyl”, by themselves or in combination with other terms refer to cyclic versions of “alkyl” and “heteroalkyl”, respectively. For heterocycloalkyl, a heteroatom can occupy the position at which the heterocycle is attached to the remainder of the molecule. Examples of cycloalkyl include cyclopentyl, cyclohexyl, 1-cyclohexenyl, 3-cyclohexenyl, cycloheptyl, and the like. Examples of heterocycloalkyl include 1-(1,2,5,6-tetrahydropyridyl), 1-piperidinyl, 2-piperidinyl, 3-piperidinyl, 4-morpholinyl, 3-morpholinyl, tetrahydrofuran-2-yl, tetrahydrofuran-3-yl, tetrahydrothien-2-yl, tetrahydrothien-3-yl, 1-piperazinyl, 2-piperazinyl and the like.

The terms “halo” or “halogen” refer to fluorine, chlorine, bromine and iodine. Additionally, terms such as “haloalkyl,” are meant to include monohaloalkyl and polyhaloalkyl.

The term “aryl” refers to a polyunsaturated, aromatic hydrocarbon that can be a single ring or multiple rings (preferably 1, 2 or 3 rings) that are fused together or linked covalently. For convenience, the term aryl may refer to divalent (i.e., arylene) and other multivalent radicals in addition to monovalent radicals. In some embodiments, aryl is a 3, 4, 5, 6, 7 or 8 membered ring that is optionally fused to one or two other 3, 4, 5, 6, 7 or 8 membered rings.

The term “heteroaryl” refers to aryl containing 1, 2, 3 or 4 heteroatoms selected from N, O and S, wherein the nitrogen and sulfur atoms are optionally oxidized, and the nitrogen atom(s) are optionally quaternized. A heteroaryl group can be attached to the remainder of the molecule through a heteroatom. Non-limiting examples of aryl and heteroaryl groups include phenyl, 1-naphthyl, 2-naphthyl, 4-biphenyl, 1-pyrrolyl, 2-pyrrolyl, 3-pyrrolyl, 3-pyrazolyl, 2-imidazolyl, 4-imidazolyl, pyrazinyl, 2-oxazolyl, 4-oxazolyl, 2-phenyl-4-oxazolyl, 5-oxazolyl, 3-isoxazolyl, 4-isoxazolyl, 5-isoxazolyl, 2-thiazolyl, 4-thiazolyl, 5-thiazolyl, 2-furyl, 3-furyl, 2-thienyl, 3-thienyl, 2-pyridyl, 3-pyridyl, 4-pyridyl, 2-pyrimidyl, 4-pyrimidyl, 5-benzothiazolyl, purinyl, 2-benzimidazolyl, 5-indolyl, 1-isoquinolyl, 5-isoquinolyl, 2-quinoxalinyl, 5-quinoxalinyl, 3-quinolyl and 6-quinolyl.

In some embodiments, any alkyl, heteroalkyl, cycloalkyl, heterocycloalkyl, aryl and heteroaryl may be substituted. Preferred substituents for each type of radical are provided below.

Substituents for alkyl, heteroalkyl, cycloalkyl and heterocycloalkyl radicals (including those groups often referred to as alkylene, alkenyl, heteroalkylene, heteroalkenyl, alkynyl, cycloalkenyl, and heterocycloalkenyl) are generically referred to as “alkyl group substituents”. In some embodiments, an alkyl group substituent is selected from —R′, —OR′, ═O, ═NR′, ═N—OR′, —NR′R″, —SR′, -halogen, —SiR′R″R″′, —OC(O)R′, —C(O)R′, —CO₂R′, —CONR′R″, —OC(O)NR′R″, —NR″C(O)R′, —NR′—C(O)NR″R″′, —NR″C(O)₂R′, —NR—C(NR′R″R′″)═NR″′, —NR—C(NR′R″)═NR′″, —S(O)R′, —S(O)₂R′, —S(O)₂NR′R″, —NRSO₂R′, —CN and —NO₂. Embodiments of R′, R″, R″′ and R″″ are provided below. Substituents for aryl and heteroaryl groups are generically referred to as “aryl group substituents”. In some embodiments, an aryl group substituent is selected from —R′, —OR′, ═O, ═NR′, ═N—OR′, —NR′R″, —SR′, -halogen, —SiR′R″R″′, —OC(O)R′, —C(O)R′, —CO₂R′, —CONR′R″, —OC(O)NR′R″, —NR″C(O)R′, —NR′—C(O)NR″R″′, —NR″C(O)₂R′, —NR—C(NR′R″R′″)═NR″″, —NR—C(NR′R″)═NR′″, —S(O)R′, —S(O)₂R′, —S(O)₂NR′R″, —NRSO₂R′, —CN, —NO₂ and —N₃. In some embodiments, R′, R″, R″′ and R″″ are each independently selected from hydrogen, substituted or unsubstituted alkyl, substituted or unsubstituted heteroalkyl, substituted or unsubstituted cycloalkyl, substituted or unsubstituted heterocycloalkyl, substituted or unsubstituted aryl and substituted or unsubstituted heteroaryl. In some embodiments, R′, R″, R′″ and R″″ are each independently selected from hydrogen, unsubstituted alkyl, unsubstituted heteroalkyl, unsubstituted cycloalkyl, unsubstituted heterocycloalkyl, unsubstituted aryl and unsubstituted heteroaryl. In some embodiments, R′, R″, R″′ and R″″ are each independently selected from hydrogen and unsubstituted alkyl (e.g., C₁, C₂, C₃, C₄, C₅ and C₆ alkyl).

Two substituents on adjacent atoms of an aryl or heteroaryl ring may optionally be replaced with a substituent of the formula -T-C(O)—(CRR′)_{q}—U—, wherein T and U are independently selected from —NR—, —O—, —CRR′— and a single bond, and q is an integer selected from 0, 1, 2 and 3. Alternatively, two of the substituents on adjacent atoms of an aryl or heteroaryl ring may optionally be replaced with a substituent of the formula -A-(CH₂)ᵣ—B—, wherein A and B are independently selected from CRR′—, —O—, —NR—, —S—, —S(O)—, —S(O)₂—, —S(O)₂NR′— and a single bond, and r is an integer selected from 1, 2, 3 and 4. One of the single bonds of the new ring so formed may optionally be replaced with a double bond. Alternatively, two of the substituents on adjacent atoms of the aryl or heteroaryl ring may optionally be replaced with a substituent of the formula —(CRR′)ₛ—X—(CR″R′″)_{d}—, where s and d are independently integers selected from 0, 1, 2 and 3, and X is selected from —O—, —NR′—, —S—, —S(O)—, —S(O)₂— and —S(O)₂NR′—. The substituents R, R′, R″ and R′″ are preferably independently selected from hydrogen and substituted or unsubstituted (C₁-C₆)alkyl.

Unless otherwise specified, the symbol “R” is a general abbreviation that represents a substituent group that is selected from H, substituted or unsubstituted alkyl, substituted or unsubstituted heteroalkyl, substituted or unsubstituted cycloalkyl, substituted or unsubstituted heterocycloalkyl, substituted or unsubstituted aryl and substituted or unsubstituted heteroaryl. When a compound includes more than one R, R′, R″, R′″ and R″″ group, they are each independently selected.

For groups with exchangeable or acidic protons, the ionized form is equally contemplated. For example, —COOH also refers to —COO⁻ while —SO₃H also refers to —SO₃⁻.

### Compositions

In one aspect, the invention provides a composition comprising (a) a first chelator chelated to a first metal and (b) a second chelator covalently bound to the first chelator. In some embodiments, the second chelator blocks solvent interaction with the first metal.

A “chelator” herein refers to a compound or a moiety thereof that can form more than one bond with a metal. The chelators that are useful in the invention include the chelators disclosed herein as well as other chelators known in the art. In some embodiments, a first chelator is selected from the group consisting of DOTA, DTPA, DO3A, DTPA-BMA, porphyrin, TREN and a derivative thereof. Useful TREN derivatives may be found, for example, in US/2005/0008570, incorporated by reference in its entirety. In some embodiments, the second chelator comprises at least one heteroatom. In exemplary embodiments, the second chelator comprises one or more sulfur atoms.

In one aspect, the invention provides a composition comprising (a) a first chelator chelated to a first metal ion and (b) a second chelator covalently bound to the first chelator, wherein the second chelator is not chelated to a second metal ion. In some embodiments, the second chelator may form a coordinate bond with the first metal ion. In these embodiments, interactions between the first metal ion and the surrounding solvent may be reduced. Thus, in some embodiments, the second chelator blocks solvent interaction with the first metal ion. This state may be referred to as being “off” although one of skill in the art will appreciate that the terms “off” and “on” are used herein simply to refer to compositions that produce two detectable signals that are distinguishable in some way (for example, being characterized by different decay rates).

In one aspect, the invention provides a composition comprising (a) a first chelator chelated to a first metal ion and (b) a second chelator covalently bound to the first chelator, wherein the second chelator is chelated to a second metal ion. In some embodiments, the second chelator does not form a coordinate bond with the first metal ion. In these embodiments, the second chelator is configured such that solvent interaction with the surrounding solvent may be increased. Thus, in some embodiments, the second chelator does not block solvent interaction with the first metal ion. This state may be referred to as being “on”.

In some embodiments, q, the number of inner-sphere solvent molecules coordinated to the first metal ion, is changed in the presence (or absence) of an analyte. In some embodiments, q, the number of inner-sphere solvent molecules coordinated to the first metal ion, is increased. In some embodiments, q, the number of inner-sphere solvent molecules coordinated to the first metal ion, is decreased.

In one aspect, the invention provides a precursor to any composition herein in which the first metal ion is absent.

In some embodiments, the first chelator is a DTPA derivative. In some embodiments, the first chelator has the structure

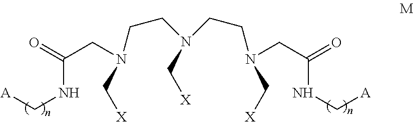

wherein n is selected from 0, 1, 2, 3, 4, 5 and 6. X is selected from COOH, CONH₂, CONR′R″, SO₃H, PO_{S}H, and SO₂NHR, wherein R, R′ and R″ are selected from H, substituted or unsubstituted alkyl, substituted or unsubstituted heteroalkyl, substituted or unsubstituted cycloalkyl, substituted or unsubstituted heterocycloalkyl, substituted or unsubstituted aryl and substituted or unsubstituted heteroaryl. M is a first metal as disclosed herein. A is a second metal chelator as disclosed herein.

In some embodiments, the first chelator is a porphyrin derivative. In some embodiments, the first chelator has the structure

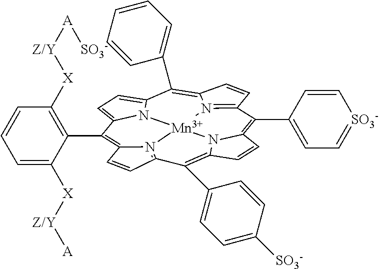

In this structure, each X, Y, Z and A is as defined for a DO3A derivative herein.

In some embodiments, the first chelator is a DO3A derivative. In some embodiments, the first chelator has the structure

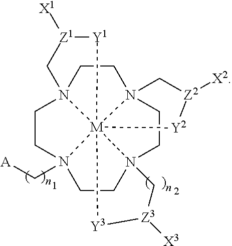

In this structure, n₁ and n₂ are independently selected from 0, 1, 2, 3, 4, 5 and 6. In some embodiments, n₁ and n₂ are independently selected from 0, 1, 2, 3 and 4. In some embodiments, n₁ and n₂ are independently selected from 0 and 1. In exemplary embodiments, n₂ is 1. In exemplary embodiments, n₁ is 0.

In some embodiments, Z¹, Z² and Z³ are independently selected from C, P and S. In exemplary embodiments, Z¹, Z² and Z³ are C.

In some embodiments, X¹, X² and X³ are independently selected from ═O, SH, CH₃ and NH₂ In some embodiments, X¹, X² and X³ are independently selected from O, S, CH and N. One of skill in the art understands that the bond between Z¹, Z² and Z³ and X¹, X² and X³ can be other than a single bond notwithstanding the depiction in the structure drawn above.

In some embodiments, Y¹, Y² and Y³ are independently selected from O and NR¹R²; wherein R¹ and R² are independently selected from H, substituted or unsubstituted alkyl, substituted or unsubstituted heteroalkyl, substituted or unsubstituted aryl, substituted or unsubstituted heteroaryl. In some embodiments, R¹ and R² are independently selected from H and substituted or unsubstituted alkyl. In some embodiments, R¹ and R² are independently selected from H and C₁, C₂, C₃, C₄, C₅ or C₆ alkyl.

A is the second chelator.

M is the first metal ion.

In exemplary embodiments, Z¹, Z² and Z³ are C, X¹, X² and X³ are ═O and Y¹, Y² and Y³ are O.

In some embodiments, A is selected from substituted or unsubstituted alkyl, substituted or unsubstituted heteroalkyl, substituted or unsubstituted cycloalkyl, substituted or unsubstituted heterocycloalkyl, substituted or unsubstituted aryl and substituted or unsubstituted heteroaryl. In some embodiments, A is substituted alkyl.

In some embodiments, A has the structure -A¹-A². In some embodiments, A¹ is selected from substituted or unsubstituted alkylene; substituted or unsubstituted heteroalkylene; substituted or unsubstituted heterocycloalkylene and substituted or unsubstituted heteroarylene. In some embodiments, A¹ is substituted alkylene. In some embodiments, A² is selected from substituted or unsubstituted heteroalkyl and substituted or unsubstituted heterocycloalkyl.

In some embodiments, A¹ has the structure —R³—R⁴—R⁵—. In some embodiments, R³ and R⁵ are independently selected from substituted or unsubstituted alkylene and substituted or unsubstituted heteroalkylene. In some embodiments, R⁴ is selected from substituted or unsubstituted heterocycloalkylene and substituted or unsubstituted heteroarylene.

In exemplary embodiments, R³ is unsubstituted alkylene. In exemplary embodiments, R⁴ is unsubstituted heteroarylene. In exemplary embodiments, R⁵ is unsubstituted alkylene.

In exemplary embodiments, A¹ has the structure

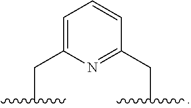

In some embodiments, A² has the structure —NR⁶R⁷. In some embodiments, R⁶ is selected from substituted or unsubstituted alkyl and substituted or unsubstituted heteroalkyl. In some embodiments, R⁷ is substituted or unsubstituted heteroalkyl. In some embodiments, R⁶ and R⁷ are optionally joined to form a ring. In some embodiments, R⁶ and R⁷ are joined via a bond or a heteroatom (e.g., S). In some embodiments, R⁶, R⁷ or both are thioether.

In some embodiments, at least one of R⁶ and R⁷ has the structure —(R⁸—R⁹)ₚ—R¹⁰. In some embodiments, p is selected from 1 and 2. In some embodiments, R⁸ is substituted or unsubstituted alkylene. In some embodiments, R⁸ is unsubstituted alkylene. In some embodiments, R⁹ is selected from S and O. In some embodiments, R¹⁰ is selected from H and substituted or unsubstituted alkyl. In some embodiments, R¹⁰ is unsubstituted alkyl.

In some embodiments, A² has the structure

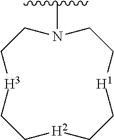

wherein H¹, H² and H³ are independently selected from S and O.

In some embodiments, A² comprises at least one sulfur atom. In some embodiments, A² is a thioether. In some embodiments, A² is a thioether comprising a nitrogen that attaches to the remainder of the compound.

In some embodiments, A² is selected from

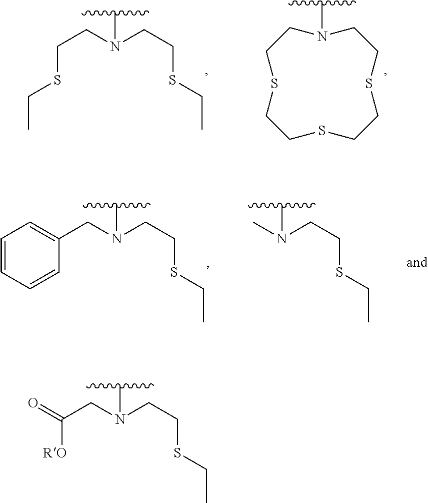

wherein R′ is selected from H and substituted or unsubstituted alkyl. In some embodiments, R′ is unsubstituted alkyl. In some embodiments, R′ is butyl.

The first chelator may bind various metals. Typically, the first chelator is chelated to a first metal that interacts with surrounding atoms (for example, solvent atoms) and affects the longitudinal relaxation rate of those surrounding atoms as understood by those of ordinary skill in the art. The terms “relaxation rate” and “relaxivity” are used interchangeably herein. Thus, the first metal may be referred to as a “relaxivity-modulating metal” or a “relaxation rate-modulating metal”. In some embodiments, the first metal is a transition metal or a lanthanide. In some embodiments, the first metal is paramagnetic. In some embodiments, the first metal is selected from any metal disclosed herein. In some embodiments, the first metal is a metal ion. In some embodiments, the first metal ion is an ion of a metal selected from the group consisting of Cr, Mn, Fe, Co, Ni, Cu, La, Ce, Pr, Nd, Pm, Sm, Eu, Gd, Tb, Dy, Ho, Er, Tm, Yb, and Lb; or any combination thereof. In some embodiments, the first metal ion is a lanthanide ion. In some embodiments, the first metal ion is an ion of a metal selected from Gd, Tb, Eu, Yb and Dy. In an exemplary embodiment, the first metal ion is Gd³⁺.

The second chelator, which is covalently bound to the first chelator, may also bind various metals. In some embodiments, the second chelator is chelated to a second metal. In some embodiments, the second chelator is not chelated to a metal. In some embodiments, the second metal is selected from any metal disclosed herein. In some embodiments, the second metal is a heavy metal, for example, a heavy metal that binds sulfur. In some embodiments, the second metal is a metal ion. In some embodiments, the second metal ion is an ion of a metal selected from the group consisting of Cu, Cd, Hg, Pb, As, Ni, Zn, Tl, Pd, Pt, Au, and Rh; or any combination thereof. In some embodiments, the second metal is a toxic heavy metal used in mining, painting or infrastructure (e.g., piping) or found in pharmaceutical waste streams. In exemplary embodiments, the second metal ion is a copper ion.

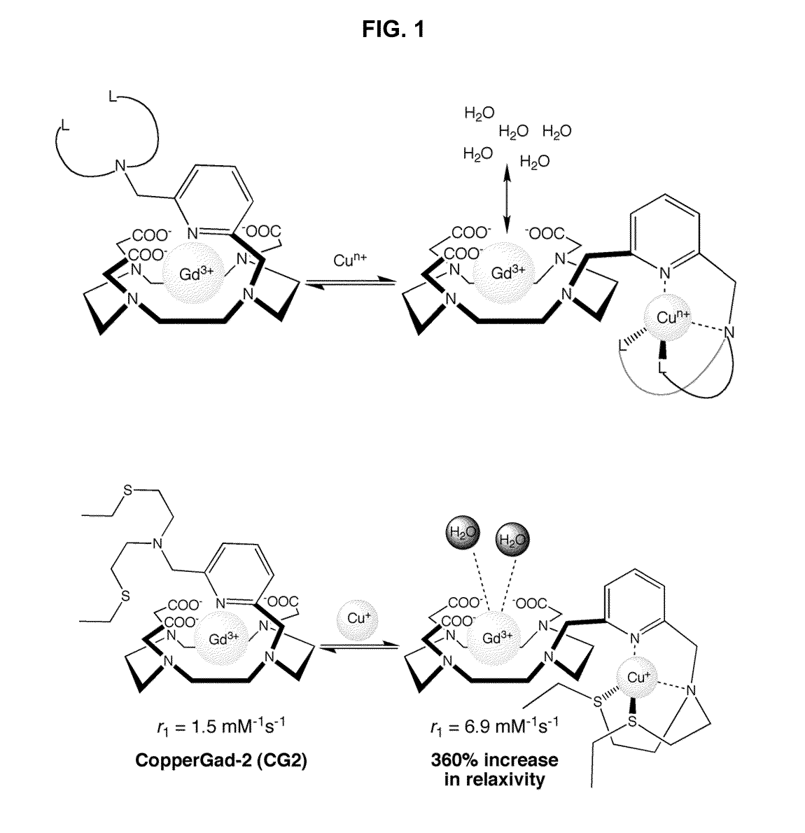

In one aspect, the invention provides a sample comprising a composition disclosed herein. In some embodiments, binding of a second metal to the second chelator results in a detectable change in the relaxivity of an atom or molecule in the sample, as compared to a sample in which the second metal is not bound to the second chelator. FIG. 1 illustrates one such embodiment, in which binding of copper to the second chelator causes a reorientation of the second chelator, allowing increased solvent interaction with the chelated first metal, in this case Gd³⁺. In this example, the second chelator sterically hinders solvent access at a coordination site of the first metal before chelation of the second metal. Chelation of the second metal to the second chelator causes displacement of the second chelator, increasing the interaction of solvent molecules with the first metal and changing the relaxivity of solvent atoms, such as the hydrogen atoms of a water molecule. As used herein, changing the relaxivity of a molecule can refer to changing the relaxivity of one or more atoms of the molecule. For convenience, the relaxivity of a composition could refer to relaxivity induced by the composition.

The first, second or any other metal disclosed herein can be in various oxidation states, for example, +1, +2, +3, and so on. Thus, in exemplary embodiments, the second metal is Cu⁺ or Cu²⁺.

In some embodiments, the metal-sensitive MRI agent is any compound disclosed herein. In some embodiments, the metal responsive MRI agent is a superparamagnetic iron oxide nanoparticle.

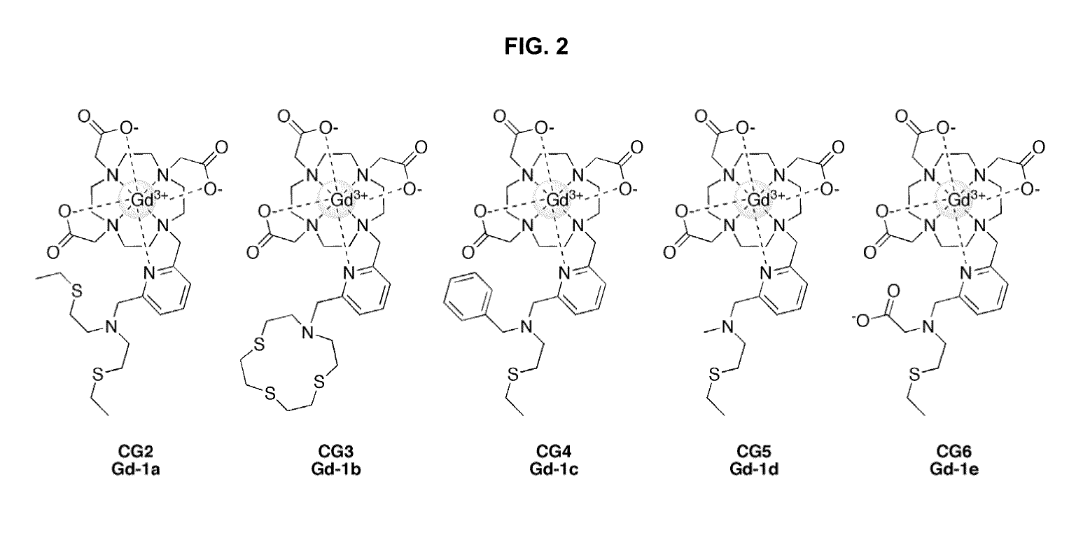

In some embodiments, the copper-activated MRI contrast agents that are members of the Copper-Gad (CG) family. These indicators comprise a Gd³⁺-DO3A core coupled to various thioether-rich receptors for copper-induced relaxivity switching. In the absence of copper ions, inner-sphere water binding to the Gd³⁺ chelate is restricted, resulting in low longitudinal relaxivity values (r₁=1.2 mM⁻¹s⁻¹ to r₁=2.2 mM⁻¹s⁻¹ measured at 60 MHz). Addition of Cu⁺ to CG2, CG3, CG4, and CG5 or either Cu⁺ or Cu²⁺ to CG6 triggers marked relaxivity enhancements (r₁=2.3 mM⁻¹s⁻¹ to r₁=6.9 mM⁻¹s⁻¹). The structures of CG2-CG6 are shown in FIG. 2. CG2 and CG3 exhibit the greatest turn-on responses, going from r₁=1.5 mM⁻¹s⁻¹ in the absence of Cu⁺ to r₁=6.9 mM⁻¹s⁻¹ upon Cu⁺ binding (360% increase). The CG sensors are highly selective for Cu⁺ and/or Cu²⁺ over competing metal ions at cellular concentrations, including Zn²⁺ at 10-fold higher concentrations. ¹⁷O NMR DIS and NMRD measurements support a mechanism in which copper-induced changes in the coordination environment of the Gd³⁺ core result in increases in g and r₁. T₁-weighted phantom images establish that the CG sensors are capable of visualizing changes in copper levels by MRI at clinical field strengths.

In some embodiments, the composition is selective for one metal ion over another metal ion. In some embodiments, the composition is selective for one metal ion over an alkali or alkali earth metal ion. In some embodiments, the composition is selective for a copper ion over a zinc ion.

### Methods

The present invention also provides methods of using any of the metal-sensitive MRI agents disclosed herein. In one aspect, the invention provides a method of assaying a sample comprising (a) contacting the sample with a composition disclosed herein; and (b) measuring a signal produced by the sample. In another aspect, the invention provides a method of detecting an analyte in a sample comprising (a) contacting the sample with a composition disclosed herein; (b) measuring a signal produced by the sample and (c) comparing the signal to a control signal generated by the composition in the absence of the analyte. In another aspect, the invention provides a method of detecting an analyte in a sample comprising (a) contacting the sample with a composition disclosed herein; (b) measuring a signal produced by the sample and (c) comparing the signal to a control signal generated by the composition in the presence of the analyte. In exemplary embodiments, the signal is an MRI signal, i.e., one that can be detected using MRI techniques as generally understood in the art.

A “sample” as used herein refers to a specimen or culture is obtained or can be obtained from a subject and includes fluids, gases and solids including for example tissue. Fluids obtainable from a subject include for example whole blood or a blood derivative (e.g. serum, plasma, or blood cells), ovarian cyst fluid, ascites, lymphatic, cerebrospinal or interstitial fluid, saliva, mucous, sputum, sweat, urine, or any other secretion, excretion, or other bodily fluids. In various exemplary embodiments, the sample comprises blood, urine or serum. As will be appreciated by those in the art, virtually any experimental manipulation or sample preparation steps may have been done on the sample. For example, wash steps may be applied to a sample. The sample may be isolated from a subject or not. In some embodiments, the sample is an ingestible substances, for example, food, as it is commonly understood.

The methods provided herein can be used, for example, in Wilson's disease assay or diagnostic; blood or serum metal (e.g., copper) analysis; urine metal (e.g., copper) analysis; blood, serum, or urine analysis of heavy metal toxicity, for example, mercury, lead, or cadmium exposure; and food analysis of, e.g., mercury, lead, or cadmium.

In some embodiments, the sample is selected from the group consisting of a fluid, a tissue and an ingestible substance. In some embodiments, the fluid is derived from an animal. In some embodiments, the fluid or tissue is isolated from an animal.

### Design and Synthesis of Copper-Responsive Magnetic Resonance Imaging Contrast Agents

Without limitation to theory, turn-on, copper-responsive sensors for magnetic resonance imaging (MRI) can rely on modulating the relaxivity of a contrast agent by action of an external trigger. Our first-generation sensor Copper-Gad-1 (CG1) combined a DO3A-type Gd³⁺ contrast agent platform with a pendant iminodiacetate site for binding Cu²⁺.¹⁹ CG1 was capable of detecting Cu²⁺ ions in aqueous solution at physiological pH. This initial CG1 design included a relatively modest turn-on response to Cu²⁺ in PBS or HEPES buffer (41% increase) and a partially disrupted Cu²⁺ response in the presence of 10-fold excess Zn²⁺. We have developed copper-activated MR sensors with improved selectivity, particularly over Zn²⁺, as well as agents that exhibit a greater sensitivity and change in relaxivity upon binding copper ions. In addition, we also targeted agents that would be activated by Cu⁺ and/or Cu²⁺, to potentially track copper in both its major oxidation states in biological systems. To achieve this goal, we appended various thioether-based copper receptors to a Gd³⁺-DO3A scaffold through a 2,6-dimethylpyridine linker switch. We reasoned that in the absence of copper ions, the pyridyl linker would cap the DO3A unit, limit inner-sphere access of water ligands to the Gd³⁺ center, and therefore minimize proton relaxivity. Binding of Cu⁺ and/or Cu²⁺ to the pyridyl-functionalized thioether receptors would reduce steric bulk around the Gd³⁺ center, affording greater inner-sphere water access to the f⁷ metal ion and an increase in relaxivity.

### EXAMPLES

### Example 1

The compositions disclosed herein can be made in a number of ways. An exemplary general synthetic route to a series of new copper-sensing MR contrast agents is outlined in Scheme 1.

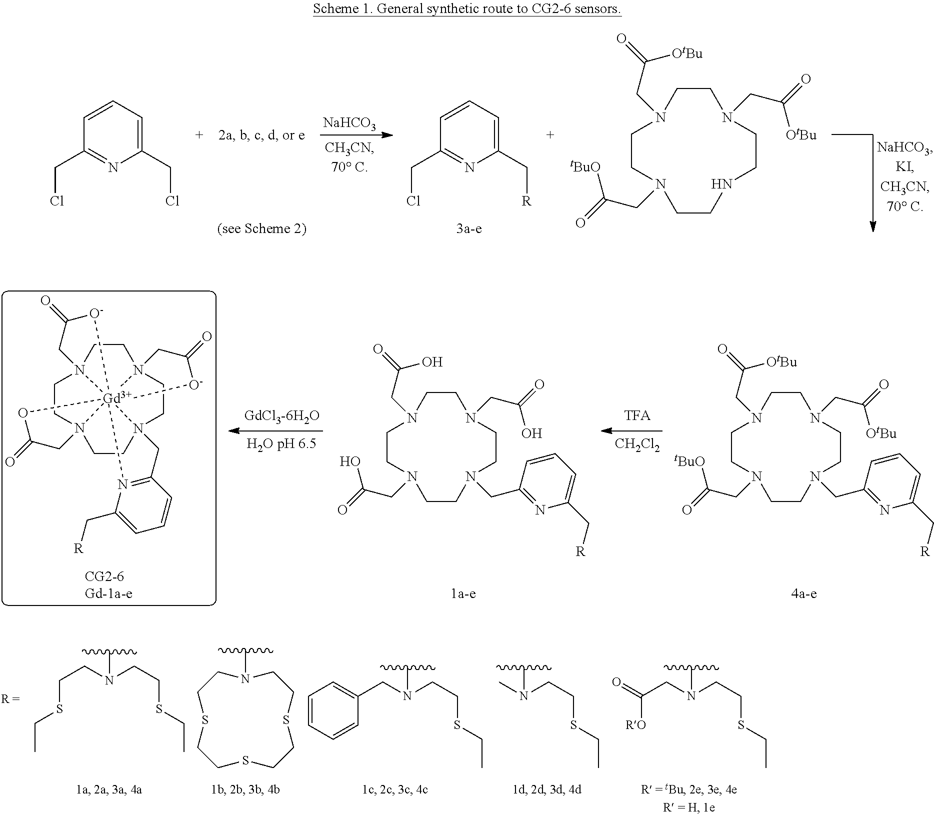

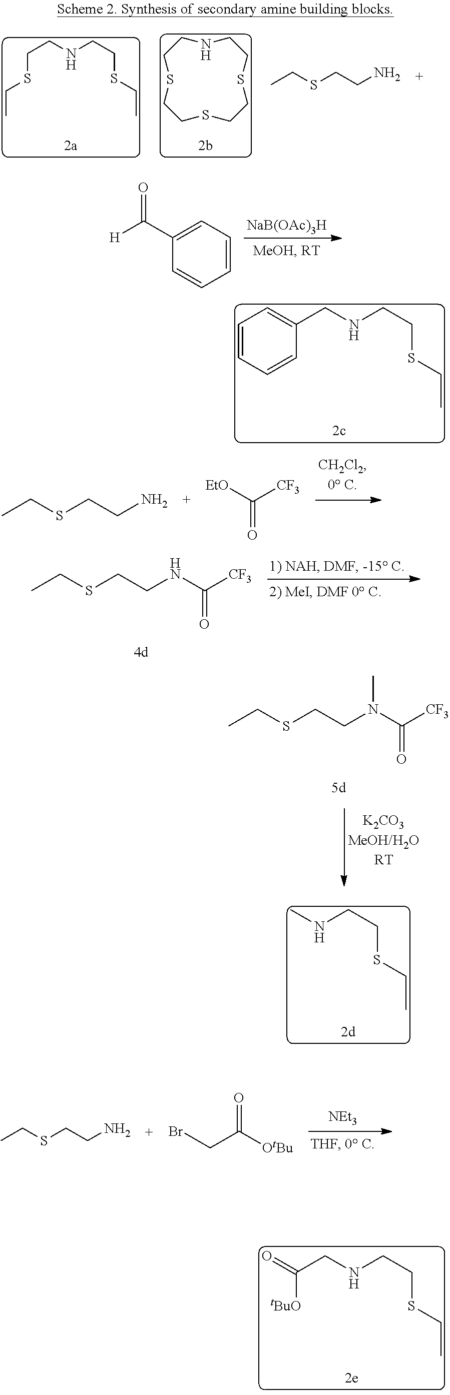

The modular synthetic strategy used to obtain Copper-Gad probes 2-6 (CG2-CG6) allows facile tuning of metal-binding properties by incorporation of a variety of aminothioether groups into the sensor portion of the contrast agent platform. The secondary amine building blocks 2a-e were prepared as shown in Scheme 2. Bis(2-(ethylthio)ethyl)amine (2a)⁷⁹ and 1,4,7-trithia-10-azacyclododecane (2b)⁸⁰ were synthesized according to literature procedures (for alternative methods, see references^{77,81-83}). N-Benzyl-2-(ethylthio)ethanamine (2c), previously synthesized from benzyl amine,⁸⁴ was obtained by reductive amination of benzaldehyde with 2-(ethylthio)ethylamine and sodium triacetoxyborohydride using conditions adapted from the synthesis of a picolyl analog.⁸⁵ We prepared the known compound 2-(ethylthio)-N-methylethanamine⁸⁶ (2d) by an alternative three-step route starting from 2-(ethylthio)ethylamine. First, 2-(ethylthio)ethylamine was reacted with ethyl trifluoroacetate to yield the secondary trifluoroacetamide 4d. The amide was deprotonated with sodium hydride and alkylated with methyl iodide in a one-pot procedure to yield 5d. Finally, the secondary amine 2d was generated in situ using potassium carbonate in 90% methanol/water and used without further purification (vide infra). Tert-butyl 2-(2-(ethylthio)ethylamino)acetate (2e) was furnished by reaction of 1 equiv of tert-butyl bromoacetate with 2-(ethylthio)ethylamine in the presence of triethylamine.

With the secondary amine precursors in hand, subsequent steps to the final Gd³⁺ contrast agents followed an identical synthetic pathway. First, reactions of 1 equiv of a given secondary amine with 2 equiv of 2,6-bis(chloromethyl)pyridine in dry acetonitrile at 70° C. in the presence of 1 equiv of sodium bicarbonate afforded the desired monochloro compounds 3a-e; employing excess 2,6-bis(chloromethyl)pyridine minimizes formation of the bis-substituted byproduct. DO3A-tris-tert-butyl ester⁸⁷⁻⁸⁹ and 3a-e are then combined in dry acetonitrile with sodium bicarbonate and potassium iodide and reacted at 65° C. for 18-48 h to give the tert-butyl protected ligands 4a-e in a manner similar to that reported by Pope.⁹⁰ Cleavage of the tert-butyl esters with TFA and purification by reverse-phase HPLC produced the desired ligands 1a-e. The ligands were then metalated with GdCl₃.6H₂O in H₂O at pH 6.5 and purified by HPLC to give the final Copper-Gad contrast agents (CG2-CG6, Gd-1a-e). Notably, HPLC purification ensures removal of any excess GdCl₃. Taken together, the new CG Gd³⁺ complexes CG2-CG6 represent a homologous series of copper-sensing MRI contrast agents bearing a range of thioether-containing receptor components.

### Example 2

### Turn-On Relaxivity Responses to Copper Ions and Electrochemistry

The longitudinal relaxivity values for the CG contrast agents in the absence or presence of copper ions were determined using T₁ measurements at 60 MHz. Studies were performed at 37° C. in 20 mM HEPES buffered to pH 7, and solutions of the purified CG sensors for relaxivity experiments contained 0.2 mM Gd³⁺ as determined by ICP-OES. Spectroscopic data are collected in Table 1.

In the absence of added copper ions, the five Gd³⁺ complexes in the series exhibit relaxivities ranging from r₁=1.2 mM⁻¹s⁻¹ (for CG5) to r₁=2.2 mM⁻¹s⁻¹ (for CG6). The low relaxivity values observed are consistent with Gd³⁺ complexes possessing limited inner-sphere water access (q=0), suggesting that the pyridine linker can effectively cap the paramagnetic Gd³⁺ center in the absence of competing metal ions. Although the CG ligand framework contains 8 atoms for lanthanide chelation, leaving one potential open site for water binding, a comparable Eu³⁺ complex containing a methyldipicolylamine substituent in the 6-position of the pyridine cap also contains zero inner-sphere water molecules as determined by luminescence lifetime measurements.⁹⁰ The steric contribution of bulky substituents in the 6-position of the pyridine cap is evident as a similar Gd³⁺ complex containing a pyridine cap with only a hydrogen group in the 6-position possesses one inner-sphere water molecule and exhibits a relaxivity of 5.3 mM⁻¹s⁻¹ at 20 MHz.⁹¹ The small variation in relaxivity values for CG2-CG6 may be due to contributions from outside the first coordination sphere of these complexes. Nuclear magnetic relaxation dispersion (NMRD) experiments provide supporting evidence for this proposal (vide infra).

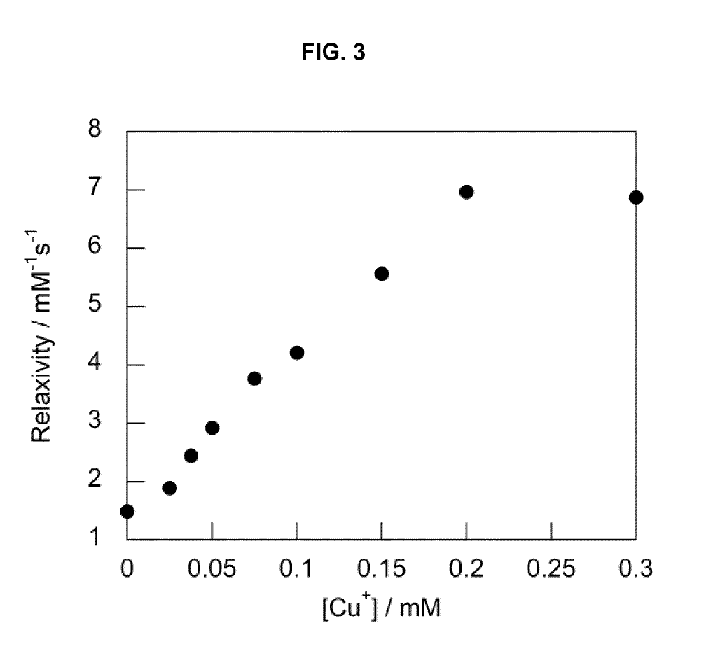

Upon addition of up to 1 equiv of copper ions, the relaxivity values of the CG contrast agents increase, establishing the ability of these probes to sense copper using the MR modality (Table 1, FIG. 3). CG2, CG3, CG4, and CG5 respond to Cu⁺ with relaxivity increases ranging from 92% to 360%. CG2 and CG3 exhibit the greatest turn-on responses, going from r₁=1.5 mM⁻¹s⁻¹ in the absence of Cu⁺ to r₁=6.9 mM⁻¹s⁻¹ upon Cu⁺ binding (360% increase). These values represent the largest relaxivity enhancements observed to date for metal-activated MR contrast agents and a ca. 9-fold improvement in copper ion response compared to CG1 (41% increase). The observed differences in turn-on Cu⁺ responses for benzyl-substituted CG4 (290% increase) versus methyl-substituted CG5 (92% increase) with the same pyridyl-thioether receptor show the marked effects that small peripheral substitutions can have on relaxivity properties.

CG6 is a unique member of the CG family that is equally responsive to both Cu⁺ and Cu²⁺. Addition of either Cu⁺ or Cu²⁺ to CG6 triggers a maximum 73% relaxivity turn-on from r₁=2.2 mM⁻¹s⁻¹ to r₁=3.8 mM⁻¹s⁻¹. Cu²⁺ itself is paramagnetic and has a r₁ value of 1.0 mM⁻¹s⁻¹ in water, measured at 10 MHz.⁹² Under the conditions used for these relaxivity measurements, Cu²⁺ does not likely contribute significantly to the copper-bound CG6 relaxivity as the relaxivity of CuSO₄ in 20 mM HEPES buffer at 60 MHz and 37° C. is <0.1 mM⁻¹s⁻¹. Monitoring the reaction of equimolar amounts of CG6 and Cu⁺ by UV-visible absorption spectroscopy reveals that the initial spectrum observed upon mixing quickly evolves (<1 min) into a spectrum that is identical to that obtained from a 1:1 solution of CG6 and Cu²⁺, suggesting a redox equilibration for this sensor that favors the higher oxidation state of copper for the N/O/S donor set provided by the pyridyl/carboxylate/thioether receptor. These data are corroborated by electrochemical Cu²⁺/Cu⁺ reduction potentials measured for the five CG complexes (Table 1). The CG2, CG3, CG4, and CG5 compounds possess very positive Cu²⁺/Cu⁺ redox couples ranging from +0.34 to +0.58 V vs SHE. On the other hand, copper-bound CG6, which responds to both Cu⁺ and Cu²⁺, has the least positive Cu²⁺/Cu⁺ reduction potential at +0.13 V.

The observed relaxivity increases for CG sensors are stable over time, indicating that the Gd³⁺-complexes remain intact in the presence of Cu^{+/2+}. We note that Cu²⁺ can catalyze the dissociation of Gd³⁺-DTPA in vivo as the affinities of DTPA for Gd³⁺ and Cu²⁺ are very similar and DTPA is kinetically labile;⁹³ however, studies with analogous Gd³⁺-DO3A complexes demonstrate that this ligand is more kinetically inert to metal ion exchange.⁹⁴ To establish the kinetic stability of the CG platforms, we monitored CG2 in the presence of 1 equiv of Cu²⁺ by LC/MS. No metal ion exchange was observed at room temperature after 7 days or at 37° C. after 4 hours.

### Example 3

### Copper Binding Stoichiometries and Affinities

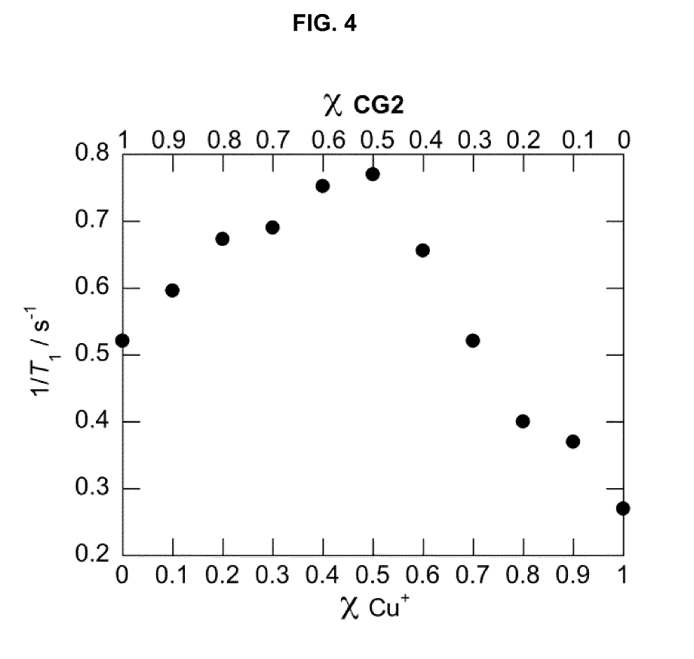

Binding analyses using the method of continuous variations (Job's plot, FIG. 4),⁹⁵ obtained through T₁ measurements (for CG2 and CG3) or UV-visible absorption measurements (for CG4, CG5, and CG6), show inflection points at 0.5 mole fraction for both the Gd³⁺ contrast agent and copper ion. Furthermore, plots of relaxivity versus [Cuⁿ⁺] reveal that the observed relaxivity for a given CG sensor reaches a maximum quantity at 1 equiv of Cuⁿ⁺ and levels off at higher added Cuⁿ⁺ concentrations (FIG. 3). These data are consistent with a 1:1 Cu:CG binding stoichiometry, which was then assumed for all K_{d} calculations.

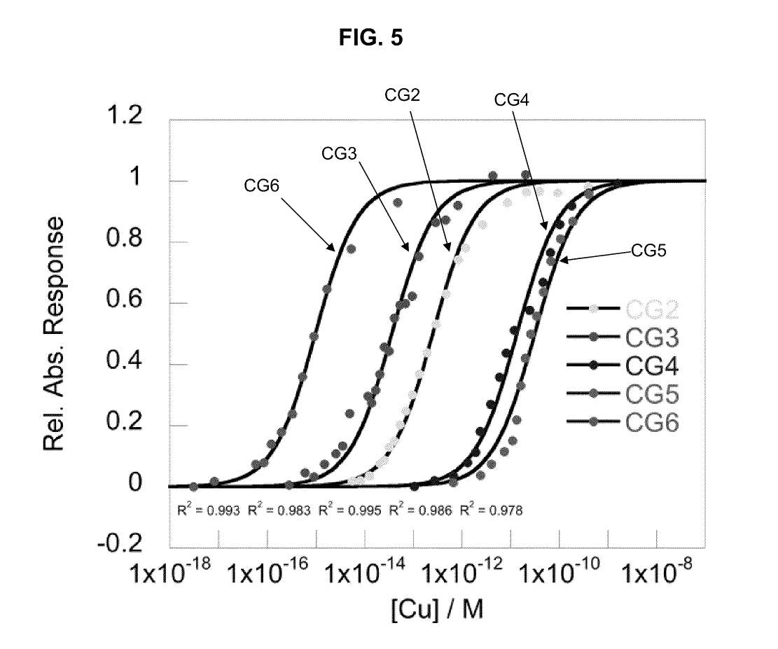

Titrations of 0.2 mM solutions of the CG contrast agents with micromolar levels of Cu⁺ or Cu²⁺ ions give linear responses, indicating that CG2-CG6 bind copper ions tightly with K_{d} values <10⁻⁶ M. K_{d} values were obtained by recording changes in the UV-visible absorption spectra of the copper-bound CG contrast agents in the presence of competing ligands with known Cu⁺ (thiourea) or Cu²⁺ (ethylenediamine) affinities.⁹⁶ Of the Cu⁺-responsive MR sensors, CG3, which possesses three thioether donors in an NS₃ macrocycle and five overall potential donor ligands for Cu⁺ binding, exhibits the highest affinity for Cu⁺ (K_{d}=3.7×10⁻¹⁴ M). The third thioether donor does not appear to play a major role in Cu⁺ binding, as CG2, which contains only two thioether donors and four overall potential donor ligands, coordinates Cu⁺ with a similar affinity (K_{d}=2.6×10⁻¹³ M, FIG. 5). The Cu⁺ affinities are further decreased in sensors that provide only three overall potential donor ligands; CG4 and CG5 bind Cu⁺ with observed dissociation constants of K_{d}=1.4×10⁻¹¹ M and K_{d}=3.2×10⁻¹¹ M, respectively. The similarity in K_{d} values between benzyl-substituted CG4 and methyl-substituted CG5 indicates that the peripheral alkyl pendant does not play a significant role in Cu⁺ binding but markedly affects relaxivity properties. CG6 binds Cu²⁺ with a much higher affinity (K_{d}=9.9×10⁻¹⁶ M) than the first-generation CG1 sensor (K_{d}=1.7×10⁻⁴ M).

### Example 4

### Selectivity Studies

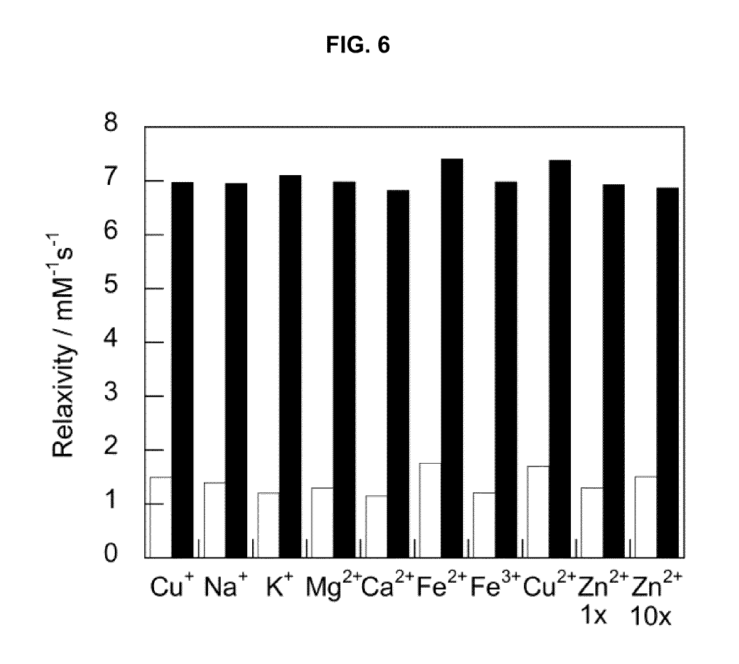

The CG sensors are highly copper-specific, and in the cases of CG2-CG5, are also selective for the Cu⁺ oxidation state, as determined by measuring their relaxivity values in the presence of other competing, biologically relevant metal ions alone or with added copper (FIG. 6). These contrast agent indicators show excellent selectivity for copper ions over abundant cellular alkali and alkaline earth metal ions at physiological levels; the addition of 10 mM Na⁺, 2 mM K⁺, 2 mM Ca²⁺, or 2 mM Mg²⁺ does not trigger relaxivity enhancements and does not interfere with copper ion turn-on responses. Likewise, introduction of d-block metal ion competitors, including 0.2 mM Zn²⁺, 0.2 mM Fe²⁺, or 0.2 mM Fe³⁺, does not activate an increase in relaxivity for the CG reagents or greatly affect their ability to sense copper ions.

With particular regard to copper/zinc specificity, a limitation of the original CG1 agent containing an iminodiacetate binding group was a partially muted turn-on response to Cu²⁺ in the presence of large excesses of Zn²⁺, a situation that can arise in certain biological environments.^{10,21,27,97} We therefore tested if our new thioether-based CG sensors would show improved specificity for copper over this first-generation design. We were delighted to observe that in all cases, turn-on relaxivity responses to Cu^{+/2+} were not affected even in the presence of Zn²⁺ levels at 10-fold excess, and that millimolar concentrations of Zn²⁺ do not give false positive responses. These data reveal that incorporation of thioether donor ligands into our CG contrast agent scaffolds serves not only to increase copper binding affinities, but also to tune against Zn²⁺ responses.

The CG series also exhibit redox specificity for copper in both its major oxidation states, Cu⁺ and Cu²⁺. CG2, CG3, CG4, and CG5 give turn-on relaxivity increases with Cu⁺ but do not respond to Cu²⁺. Moreover, the presence of Cu²⁺ does not interfere with the Cu⁺-activated enhancements for these four contrast agents. CG6 responds to both Cu⁺ and Cu²⁺ with the same relaxivity turn-on, whereas CG1 is sensitive only to Cu²⁺ and not Cu⁺. The potential ability of this new family of CG sensors to sense bioavailable copper pools in either or both its predominant oxidation states represents a significant advance over the initial CG1 compound.

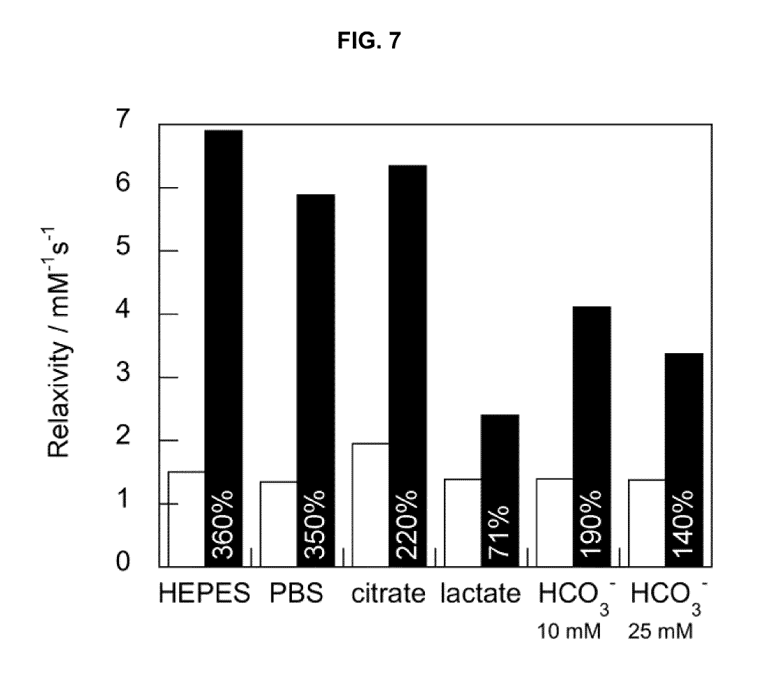

We also tested the copper responses of CG2-6 in the presence of physiologically relevant concentrations of common biological anions (FIG. 7). Parker has shown that Gd³⁺-DO3A-based complexes can bind anions including phosphate, carbonate, lactate, and citrate,^{98,99,43,100} and Eu³⁺- and Tb³⁺-DO3A-type complexes have been developed as luminescent anion sensors.¹⁰¹⁻¹⁰⁷ Phosphate anions do not bind strongly to CG2 as measurements in phosphate buffered saline (PBS, 10 mM phosphate) reveal a 350% increase in relaxivity in response to Cu⁺. Carboxylate-type anions, however, can affect relaxivity responses of Cu⁺-bound CG2. Addition of citrate (0.13 mM) and lactate (2.3 mM) to CG2 results in turn-on responses to Cu⁺ of 220% and 71% respectively. Carbonate concentrations also affect the response of CG2; the effect of carbonate was tested at 10 mM NaHCO₃ (intracellular)¹⁰⁴ and 25 mM NaHCO₃ (extracellular)¹⁰⁸ and gave increases in r₁ in response to Cu⁺ of 190% and 140% respectively. Although the relaxivity increases observed in the presence of anions are still well within a range detectable by MRI,¹⁰⁹ current work is geared toward developing CG-sensors with more carboxylate functionalities incorporated into the ligand framework to minimize anion sensitivity.^{55,110}

### Example 5

### Dysprosium-Induced ¹⁷O NMR Shift Experiments

After establishing the ability of the CG sensors to selectively detect Cu⁺ and/or Cu²⁺ by changes in longitudinal relaxivity values, we next sought to probe aspects of their mechanism of action. Based on our molecular design, we reasoned that the relaxivity differences observed for CG contrast agents in the absence or presence of Cu⁺ and/or Cu²⁺ ions are in part due to changes in q, the number of inner-sphere water molecules coordinated to the paramagnetic Gd³⁺ center. Initial experiments to probe this question employed standard luminescence methods developed by Horrocks,¹¹ but attempts to obtain q by measuring luminescence lifetimes of Eu³⁺ and Tb³⁺ analogs of CG2 in the absence or presence of Cu⁺ were unsuccessful, as Cu⁺-containing solutions gave luminescence decays that were best fit to multiple lifetimes both in H₂O and D₂O. We suspected that additional quenching pathways beyond those involving inner-sphere H₂O molecules on the lanthanide center may play a role in this system. Cu⁺-binding could lead to quenching of the S₁ excited state of the pyridine antenna by electron transfer, thus eliminating energy transfer to the lanthanide ion and the luminescent output. Cu⁺ is known to quench fluorescence of ligands such as bathocuproine disulfonate.¹¹² In addition, a Eu³⁺ complex containing a phenanthroline unit for metal ion binding experiences quenched emission in the presence of Cu²⁺.¹¹³

To circumvent these issues, we turned our attention to an alternative method for obtaining q values, namely the application of ¹⁷O NMR spectroscopy to Dy³⁺ analogs of the CG sensors (DyCG2-6).¹¹⁴ Specifically, interactions of water ligands with paramagnetic Dy³⁺ ions lead to an upfield shift of the ¹⁷O signals of H₂O in a manner proportional to both the concentration of Dy³⁺ and q. Moreover, this lanthanide-induced shift is largely insensitive to the non-water ligands coordinated to the paramagnetic metal center.¹¹⁴ Dysprosium-induced shift (DIS) experiments for CG2 and CG3 were performed in 20 mM HEPES buffered to pH 7; CG4 and CG5 spectra were acquired in 10% acetonitrile in 20 mM HEPES buffered to pH 7 owing to solubility and stability of the Cu⁺-bound complexes at higher Dy³⁺ concentrations required for the DIS measurements (1-200 mmol/kg H₂O). Dy concentrations were calculated using molality (with respect to H₂O) since the ¹⁷O shift represents the interaction between Dy³⁺ and H₂O; addition of CH₃CN aids in stabilizing certain complexes but should not affect the DIS. The spectral results were calibrated to a DyCl₃ standard (q=9) to determine the number of bound water molecules for the CG sensors with and without added Cu⁺. A plot of varying DyCl₃ concentrations versus DIS in pH 7 HEPES buffer has a slope of 324 ppm/(mol/kg H₂O), which corresponds to a 36 ppm/(mol/kg H₂O) shift per bound water molecule. A similar DIS plot for DyCl₃ in 10% acetonitrile in 20 mM pH 7 HEPES buffer exhibits a slope of 362 ppm/(mol/kg H₂O), which corresponds to 40 ppm/(mol/kg H₂O) per bound water molecule. Data for DyCG2-5 are presented in Table 2.

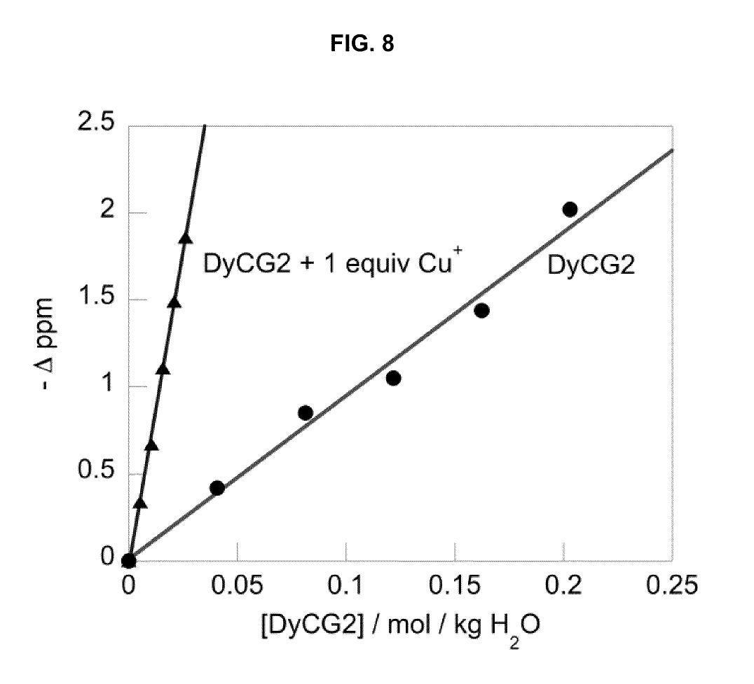

The effects of DyCG2 on the chemical shift of ¹⁷O-labeled H₂O were determined in the absence and presence of 1 equiv Cu⁺ at various concentrations of Dy³⁺ (FIG. 8). In the absence of Cu⁺, the measured ¹⁷O shift response for DyCG2 is 9 ppm/(mol/kg H₂O), corresponding to q=0.3. When 1 equiv of Cu⁺ is added, the observed shift response increases to 72 ppm/(mol/kg H₂O), corresponding to q=2.0. These data are consistent with the proposal that modulating the number of inner-sphere water molecules plays a role in the copper-activated relaxivity changes sensed by the CG contrast agents. Similarly, the DyCG3 DIS plot displays a slope of 11 ppm/(mol/kg H₂O) in the absence of Cu⁺, corresponding to q=0.3; addition of 1 equiv of Cu⁺ increases the slope to 79 ppm/(mol/kg H₂O), corresponding to q=2.2. DIS measurements of DyCG4 and DyCG5 without Cu⁺ show slopes of 7 ppm/(mol/kg H₂O) (q=0.2) and 12 ppm/(mol/kg H₂O) (q=0.3), respectively. Cu⁺ binding increases the DIS slopes for DyCG4 and DyCG5 to 84 ppm/(mol/kg H₂O) (q=2.1) and 41 ppm/(mol/kg H₂O) (q=1.0), respectively. Notably, direct comparison of the Δq values obtained for DyCG4 and DyCG5 reveal a lower DIS value for the latter, which is consistent with the smaller turn-on increase in r₁ observed for this compound.

### Example 6

### Nuclear Magnetic Relaxation Dispersion Profiles

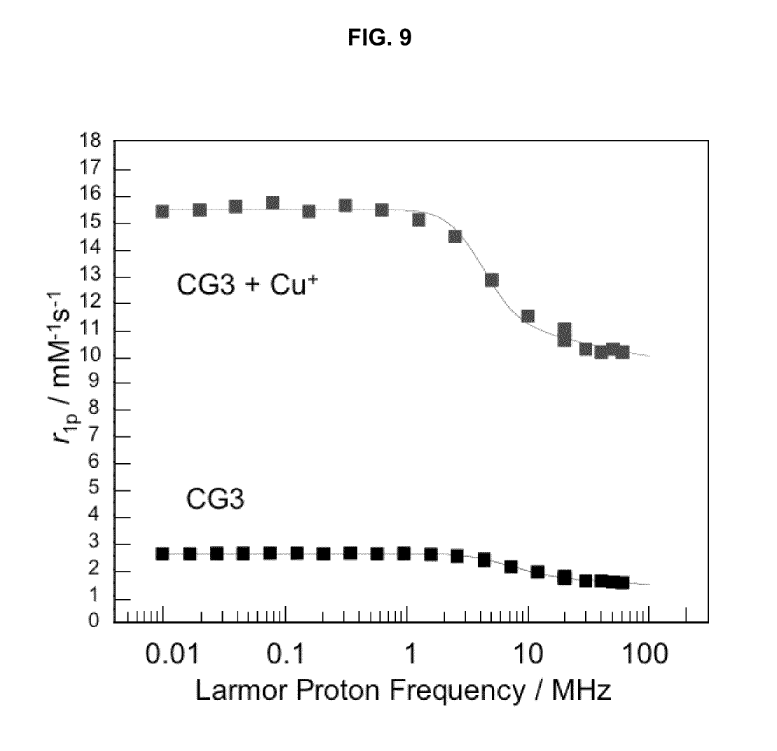

As a secondary, independent set of experiments to further probe the mechanisms of copper ion sensing by the CG contrast agents, we also performed nuclear magnetic relaxation dispersion (NMRD) measurements of these sensors in the absence and in the presence of copper ions using a field cycling relaxometer (FIG. 9). The profiles obtained were analyzed following Solomon-Bloembergen-Morgan theory³⁶⁻³⁸ for the inner-sphere relaxivity and the Freed model¹¹⁵ for the outer-sphere relaxivity, fixing the diffusion coefficient (D) at 2.24×10⁵ cm²s⁻¹, the distance between Gd³⁺ and the inner sphere water protons (r) at 3.1 Å, and the inner sphere exchange lifetime (τ_{M}) at 160 ns, the reported value for the parent complex Gd³⁺-DO3A. Profiles were obtained for all compounds in the copper-free state. Profiles in the presence of Cuⁿ⁺ were obtained for CG2-4 (Cu⁺) and CG6 (Cu²⁺). For CG5, a NMRD profile could not be obtained for the Cu⁺-bound complex due to its low relaxivity and the low solubility of Cu⁺ in solution, which resulted in a high degree of error in the measurements. The fitted values are displayed in Table 3.

NMRD data acquired for the CG series of compounds in the absence of added copper ions are consistent with Gd³⁺ contrast agents that do not possess any inner-sphere water molecules. In fact, the measured outer-sphere relaxivities were so low that, in order to obtain a reasonable fit, the distance of closest approach of outer-sphere water protons (a) was allowed to vary. The distances obtained for the CG complexes (4.2-4.8 Å) were markedly longer than what is observed for typical Gd³⁺ contrast agents with greater water access (3.8-4 Å). These values correlate with the copper-free relaxivities of CG2-6; longer a values give lower relaxivities and shorter a values give higher relaxivities. For Cu⁺-sensing agents CG2-4, the estimated change in q of 2 as determined by DIS measurements was also observed in the fitted NMRD data. In fact, any attempt to fit the observed NMRD profiles with q=1 led to very poor agreement between experimental and calculated values. The change in q of 1 for CG6 upon addition of Cu²⁺ as determined by NMRD is consistent with the lower turn-on response observed with this complex compared to CG2-4. The reduced q modulation for CG6 relative to CG2-4 could indicate that the carboxylic acid moiety used for Cu²⁺ binding also interacts with the Gd³⁺ center in the Cu²⁺-bound state. The fitted rotational correlation times (τ_{R}) for copper-bound CG complexes all fall within the range expected for Gd³⁺ complexes with molecular weights of 700-800 D. τ_{R} values for copper-free CG2-6 were fixed to values close to their copper-bound analogues as fits of NMRD data for q=0 complexes are not sensitive to small changes in τ_{R}. The values of Δ² (average quadratic transient zero field splitting), τᵥ (electronic correlation time), and τₛ₀ (electronic relaxation time at zero field), which govern the electronic relaxation time, are relatively similar to each other. These NMRD values are closer to those of Gd³⁺-DTPA than Gd³⁺-DOTA, reflecting the asymmetry of CG2-6.⁶⁴

### Example 7

### Copper-Activated T₁-Weighted Phantom Magnetic Resonance Imaging

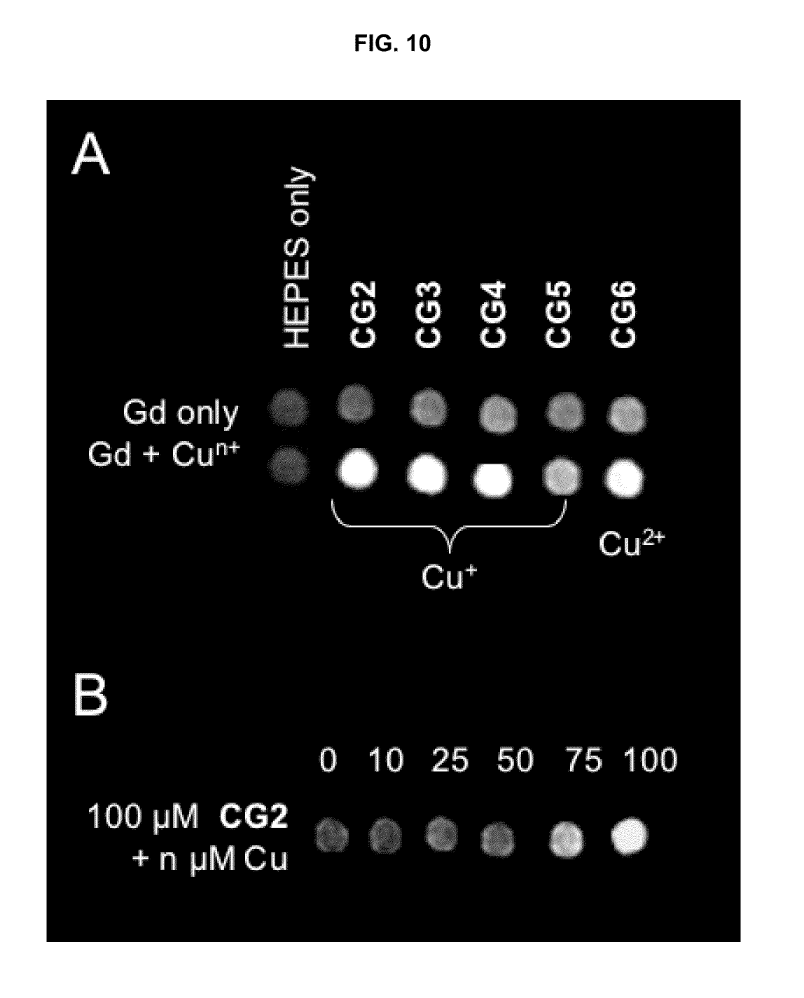

With spectroscopic data showing the turn-on relaxivity responses, binding properties, metal ion selectivities, and copper-induced changes in q values for this new series of CG contrast agents in hand, we next sought to test the ability of these sensors to detect changes in aqueous Cu⁺ and/or Cu²⁺ levels using MRI. To demonstrate the potential feasibility of these MR sensors for molecular imaging applications, we acquired T₁-weighted images of the CG complexes in the absence or presence of copper ions with a commercial 1.5 T magnet (Avanto Siemens MRI system). Phantom MR images depicted in FIG. 10A show that all the CG sensors can detect contrast between samples with and without added copper ions with clinically relevant field strengths. Moreover, images of 100 μM CG2 with Cu⁺ added at 0, 10, 25, 50, 75, and 100 μM concentrations (FIG. 10B) reveal that this MR probe can readily visualize differences in copper levels in a biologically relevant μM range given a known contrast agent concentration. In this context, chelatable copper pools have been identified in the mitochondrial matrix²² and in the Golgi apparatus.²³ Moreover, the cerebrospinal fluid (CSF) contains micromolar levels of copper ions, most of which is not bound to ceruloplasmin due to the low concentrations of this protein in the CSF,^{24,25} which may result in facile exchange between different copper binding ligands.²⁶

The articles “a,” “an” and “the” as used herein do not exclude a plural number of the referent, unless context clearly dictates otherwise. The conjunction “or” is not mutually exclusive, unless context clearly dictates otherwise. The term “include” refers to nonexhaustive examples.

All references, publications, patent applications, issued patents, accession records, databases, websites and document urls cited herein are incorporated by reference in their entirety for all purposes.

TABLE 1
Relaxivity values of CG2-6 at 60 MHz in the absence and
presence of Cu⁺ or Cu²⁺, Cu^{2+/+} reduction potentials,
and apparent dissociation constants (K_{d})

| | | | | Cu^{2+/+} | |
|---|---|---|---|---|---|
| | r₁^{a} (no Cu)/ | r₁^{a} (1 equiv Cu)/ | % increase | E_{1/2}^{d}/ | K_{d}^{e}/ |
| | mM⁻¹s⁻¹ | mM⁻¹s⁻¹ | in r₁ | V vs. SHE | M |
| CG2 | 1.5 | 6.9^{b} | 360% | 0.46 | 2.6 × 10^{-13b} |
| CG3 | 1.5 | 6.9^{b} | 360% | 0.58 | 3.7 × 10^{-14b} |
| CG4 | 1.7 | 6.6^{b} | 290% | 0.40 | 1.4 × 10^{-11b} |
| CG5 | 1.2 | 2.3^{b} | 92% | 0.34 | 3.2 × 10^{-11b} |
| CG6 | 2.2 | 3.8^{b,c} | 73% | 0.13 | 9.9 × 10^{-16c} |

^{a}Measured in 20 mM HEPES buffer, pH 7, 37° C.
^{b}Cu⁺.
^{c}Cu²⁺.
^{d}Measured in PBS buffer, pH 7.4.
^{e}Measured in 20 mM HEPES buffer, pH 7, 25° C.

TABLE 2
Estimated q values for copper sensing MRI contrast agents
in the absence and presence of copper ions as determined
from ¹⁷O dysprosium induced shift (DIS) measurements.

| | | −Δ ppm/[Dy]/q | |
|---|---|---|---|
| | Conditions | ppm/(mol/kg H₂O) | |
| DyCl₃ | 20 mM HEPES, pH 7 | 324 | 9^{a} |
| DyCl₃ | 10% CH₃CN in 20 mM HEPES pH 7 | 362 | 9^{a} |
| DyCG2 | 20 mM HEPES, pH 7 | 9 | 0.3^{b} |
| DyCG2 + Cu⁺ | | 72 | 2^{a} |
| DyCG3 | 20 mM HEPES, pH 7 | 11 | 0.3^{b} |
| DyCG3 + Cu⁺ | | 79 | 2.2^{b} |
| DyCG4 | 10% CH₃CN in 20 mM HEPES pH 7 | 7 | 0.2^{c} |
| DyCG4 + Cu⁺ | | 84 | 2.1^{c} |
| DyCG5 | 10% CH₃CN in 20 mM HEPES pH 7 | 12 | 0.3^{c} |
| DyCG5 + Cu⁺ | | 41 | 1.0^{c} |

^{a}See reference 90.
^{b}Calculated based on values from q = 9 DyCl₃ in 20 mM HEPES pH 7.
^{c}Calculated based on values from q = 9 DyCl₃ in 10% CH₃CN in 20 mM HEPES pH 7.

TABLE 3
Best-fit values for CG2-6 in the absence and presence of Cu^{+/2+} to
Solomon-Bloembergen-Morgan equations as determined from NMRD experiments.^{a}

| | r₁ₚ/mM⁻¹s⁻¹ | | | | | | |
|---|---|---|---|---|---|---|---|
| | 20 MHz | | | | | | |
| | 25° C. | a/Å | q | τ_{R}/ps | Δ²/10¹⁹ s⁻² | τᵥ/ps | τₛ₀/ps |
| CG2 | 1.6 | 4.7 ± 0.11 | 0^{c} | 110^{d} | 5.8 ± 1.1 | 19 ± 2.4 | 75.6 |
| CG2 + Cu⁺ | 9.3 | 3.8^{c} | 2.00 ± 0.22 | 110 ± 12.3 | 5.6 ± 0.4 | 22 ± 1.4 | 67.6 |
| CG3 | 1.6 | 4.7 ± 0.09 | 0^{c} | 130^{d} | 3.2 ± 0.7 | 27 ± 4.4 | 96 |
| CG3 + Cu⁺ | 10.5 | 3.8^{c} | 2.03 ± 0.24 | 128 ± 14.5 | 2.0 ± 0.6 | 42 ± 9.2 | 99 |
| CG4 | 2.1 | 4.2 ± 0.15 | 0^{c} | 130^{d} | 3.4 ± 1.4 | 25 ± 7.7 | 99 |
| CG4 + Cu⁺ | 10.4 | 3.8^{c} | 2.06 ± 0.26 | 128 ± 15.5 | 2.5 ± 0.8 | 37 ± 8.1 | 90 |
| CG5 | 1.6 | 4.8 ± 0.12 | 0^{c} | 100^{e} | 3.5 ± 0.8 | 25 ± 4.2 | 95 |
| CG5 + Cu^{+b} | — | — | — | — | — | — | — |
| CG6 | 2.2 | 4.2 ± 0.13 | 0^{c} | 80^{d} | 8.4 ± 2.0 | 16 ± 2.7 | 61 |
| CG6 + Cu²⁺ | 4.8 | 3.8^{c} | 1 ± 0.18 | 78 ± 2.9 | 5.4 ± 0.6 | 17 ± 1.6 | 90 |

^{a}Measurements acquired at 25° C. in 20 mM HEPES at pH 7. Relaxivity values for copper free CG2-6 and CG6 + Cu²⁺ and were measured at 0.5 mM concentrations. Cu⁺-containing solutions were measured at 0.1 mM due to low solubility of Cu⁺ in aqueous solution. The contribution to the observed relaxivity by Cu²⁺ has been included in the outer-sphere term but is likely to be negligible.
^{b}Relaxivity too low to perform NMRD measurements at 0.1 mM concentrations.
^{c}Fixed in the fitting procedure.
^{d}Values were not experimentally determined and were assumed to be equal to the corresponding complexes where q ≠ 0.
^{e}Given the similarity in structure between CG2-6, the τ_{R} value for CG5 was set to the average τ_{R} value of the other complexes.

### CITATIONS

(1) Puig, S.; Thiele, D. J. Curr. Opin. Chem. Biol. 2002, 6, 171-180.
(2) Prohaska, J. R.; Gybina, A. A. J. Nutr. 2004, 134, 1003-1006.
(3) Cater, M. A.; Mercer, J. F. B. In Top. Curr. Genet. 2006; Vol. 14, p 101-129.
(4) Schlief, M.; Gitlin, J. Mol. Neurobiol. 2006, 33, 81-90.
(5) Maryon, E. B.; Molloy, S. A.; Zimnicka, A. M.; Kaplan, J. H. BioMetals 2007, 20, 355-364.
(6) Leary, S. C.; Winge, D. R.; Cobine, P. A. BBA-Mol. Cell. Res. 2009, 1793, 146-153.
(7) Turski, M. L.; Thiele, D. J. J. Biol. Chem. 2009, 284, 717-721.
(8) Waggoner, D. J.; Bartnikas, T. B.; Gitlin, J. D. Neurobiol. Dis. 1999, 6, 221-230.
(9) Bayer, T. A.; Wirths, O.; MajtÈnyi, K.; Hartmann, T.; Multhaup, G.; Beyreuther, K.; Czech, C. Brain Pathol. 2001, 11, 1-11.
(10) Barnham, K. J.; Masters, C. L.; Bush, A. I. Nat. Rev. Drug Discov. 2004, 3, 205-214.
(11) Valentine, J. S.; Doucette, P. A.; Potter, S. Z. Ann. Rev. Biochem. 2005, 74, 563-593.
(12) Culotta, V. C.; Yang, M.; O'Halloran, T. V. BBA-Mol. Cell. Res. 2006, 1763, 747-758.
(13) Gaggelli, E.; Kozlowski, H.; Valensin, D.; Valensin, G. Chem. Rev. 2006, 106, 1995-2044.
(14) Donnelly, P. S.; Xiao, Z.; Wedd, A. G. Curr. Opin. Chem. Biol. 2007, 11, 128-133.
(15) Millhauser, G. L. Ann. Rev. Phys. Chem. 2007, 58, 299-320.
(16) Davies, P.; Brown, D. R. Biochem. J. 2008, 410, 237-244.
(17) Zeng, L.; Miller, E. W.; Pralle, A.; Isacoff, E. Y.; Chang, C. J. J. Am. Chem. Soc. 2006, 128, 10-11.
(18) Miller, E. W.; Zeng, L.; Domaille, D. W.; Chang, C. J. Nat. Protocols 2006, 1, 824-827.
(19) Que, E. L.; Chang, C. J. J. Am. Chem. Soc. 2006, 128, 15942-15943.
(20) Domaille, D. W.; Que, E. L.; Chang, C. J. Nat. Chem. Biol. 2008, 4, 168-175.
(21) Que, E. L.; Domaille, D. W.; Chang, C. J. Chem. Rev. 2008, 108, 1517-1549.
(22) Cobine, P. A.; Ojeda, L. D.; Rigby, K. M.; Winge, D. R. J. Biol. Chem. 2004, 279, 14447-14455.
(23) Yang, L. C.; McRae, R.; Henary, M. M.; Patel, R.; Lai, B.; Vogt, S.; Fahrni, C. J. Proc. Natl. Acad. Sci. USA 2005, 102, 11179-11184.
(24) Weisner, B.; Hartard, C.; Dieu, C. J. Neurol. Sci. 1987, 79, 229-237.
(25) Hartard, C.; Weisner, B.; Dieu, C.; Kunze, K. J. Neurol. 1993, 241, 101-107.
(26) Peña, M. M. O.; Lee, J.; Thiele, D. J. J. Nutr. 1999, 129, 1251-1260.
(27) Bush, A. I. Curr. Opin. Chem. Biol. 2000, 4, 184-191.
(28) Aime, S.; Fasano, M.; Terreno, E. Chem. Soc. Rev. 1998, 27, 19-29.
(29) Caravan, P.; Ellison, J. J.; McMurry, T. J.; Lauffer, R. B. Chem. Rev. 1999, 99, 2293-2352.
(30) Tóth, É.; Burai, L. s.; Merbach, A. E. Coord. Chem. Rev. 2001, 216-217, 363-382.
(31) Aime, S.; Botta, M.; Terreno, E. In Adv. Inorg. Chem. 2005, p 173-238.
(32) Raymond, K. N.; Pierre, V. C. Bioconj. Chem. 2005, 16, 3-8.
(33) Bünzli, J.-C. G. Acc. Chem. Res. 2006, 39, 53-61.
(34) Woods, M.; Woessner, D. E.; Sherry, A. D. Chem. Soc. Rev. 2006, 35, 500-511.
(35) Werner, E. J.; Datta, A.; Jocher, C. J.; Raymond, K. N. Angew. Chem., Int. Ed 2008, 47, 2-15.
(36) Solomon, I. Phys. Rev. 1955, 99, 559-565.
(37) Bloembergen, N. J. Chem. Phys. 1957, 27, 572-573.
(38) Bloembergen, N.; Morgan, L. O. J. Chem. Phys. 1961, 34, 842-850.
(39) Moats, R. A.; Fraser, S. E.; Meade, T. J. Angew. Chem., Intl. Ed. Engl. 1997, 36, 726-728.
(40) Louie, A. Y.; Hüber, M. M.; Ahrens, E. T.; Rothbächer, U.; Moats, R.; Jacobs, R. E.; Fraser, S. E.; Meade, T. J. Nat. Biotech. 2000, 18, 321-325.
(41) Nivorozhkin, A. L.; Kolodziej, A. F.; Caravan, P.; Greenfield, M. T.; Lauffer, R. B.; McMurry, T. J. Angew. Chem., Int. Ed. 2001, 40, 2903-2906.
(42) Zhao, M.; Josephson, L.; Tang, Y.; Weissleder, R. Angew. Chem., Int. Ed. 2003, 42, 1375-1378.
(43) Duimstra, J. A.; Femia, F. J.; Meade, T. J. J. Am. Chem. Soc. 2005, 127, 12847-12855.
(44) Querol, M.; Chen, J. W.; Weissleder, R.; Bogdanov, A. Org. Lett. 2005, 7, 1719-1722.
(45) Wei, Q.; Seward, G. K.; Hill, P. A.; Patton, B.; Dimitrov, I. E.; Kuzma, N. N.; Dmochowski, I. J. J. Am. Chem. Soc. 2006, 128, 13274-13283.
(46) Yoo, B.; Pagel, M. D. J. Am. Chem. Soc. 2006, 128, 14032-14033.
(47) Giardiello, M.; Lowe, M. P.; Botta, M. Chem. Commun. 2007, 4044-4046.
(48) Breckwoldt, M. O.; Chen, J. W.; Stangenberg, L.; Aikawa, E.; Rodriguez, E.; Qiu, S.; Moskowitz, M. A.; Weissleder, R. Proc. Natl. Acad. Sci. USA 2008, 105, 18584-18589.
(49) Chauvin, T.; Durand, P.; Bernier, M.; Meudal, H.; Doan, B.-T.; Noury, F.; Badet, B.; Beloeil, J.—C.; Tóth, É. Angew. Chem., Int. Ed. 2008, 47, 4370-4372.
(50) Hanaoka, K.; Kikuchi, K.; Terai, T.; Komatsu, T.; Nagano, T. Chem. Eur. J. 2008, 14, 987-995.
(51) Mizukami, S.; Takikawa, R.; Sugihara, F.; Hori, Y.; Tochio, H.; Walchli, M.; Shirakawa, M.; Kikuchi, K. J. Am. Chem. Soc. 2008, 130, 794-795.
(52) Hall, J.; Ha\ddot{n}er, R.; Aime, S.; Botta, M.; Faulkner, S.; Parker, D.; Sousa, A. S. New J. Chem. 1998, 22, 627-631.
(53) Aime, S.; Crich, S. G.; Botta, M.; Giovenzana, G.; Palmisano, G.; Sisti, M. Chem. Commun. 1999, 1577-1578.
(54) Zhang, S.; Wu, K.; Sherry, A. D. Angew. Chem., Int. Ed. 1999, 38, 3192-3194.
(55) Lowe, M. P.; Parker, D.; Reany, O.; Aime, S.; Botta, M.; Castellano, G.; Gianolio, E.; Pagliarin, R. J. Am. Chem. Soc. 2001, 123, 7601-7609.
(56) Aime, S.; Castelli, D. D.; Terreno, E. Angew. Chem., Int. Ed. 2002, 41, 4334-4336.
(57) Woods, M.; Kiefer, G. E.; Bott, S.; Castillo-Muzquiz, A.; Eshelbrenner, C.; Michaudet, L.; McMillan, K.; Mudigunda, S. D. K.; Ogrin, D.; Tircso, G.; Zhang, S.; Zhao, P.; Sherry, A. D. J. Am. Chem. Soc. 2004, 126, 9248-9256.
(58) Tóth, É.; Bolskar, R. D.; Borel, A.; Gonzalez, G.; Helm, L.; Merbach, A. E.; Sitharaman, B.; Wilson, L. J. J. Am. Chem. Soc. 2005, 127, 799-805.
(59) Zhang, S.; Trokowski, R.; Sherry, A. D. J. Am. Chem. Soc. 2003, 125, 15288-15289.
(60) Trokowski, R.; Zhang, S.; Sherry, A. D. Bioconj. Chem. 2004, 15, 1431-1440.
(61) Aime, S.; Delli Castelli, D.; Fedeli, F.; Terreno, E. J. Am. Chem. Soc. 2002, 124, 9364-9365.
(62) Liu, G.; Li, Y.; Pagel, M. D. Magn. Reson. Med. 2007, 58, 1249-1256.
(63) Li, W.-H.; Fraser, S. E.; Meade, T. J. J. Am. Chem. Soc. 1999, 121, 1413-1414.
(64) Li, W.-H.; Parigi, G.; Fragai, M.; Luchinat, C.; Meade, T. J. Inorg. Chem. 2002, 41, 4018-4024.
(65) Atanasijevic, T.; Shusteff, M.; Fam, P.; Jasanoff, A. Proc. Natl. Acad. Sci. USA 2006, 103, 14707-14712.
(66) Angelovski, G.; Fouskova, P.; Mamedov, I.; Canals, S.; Tóth, É.; Logothetis, N. K. ChemBioChem 2008, 9, 1729-1734.
(67) Dhingra, K.; Fousková, P.; Angelovski, G.; Maier, M.; Logothetis, N.; Tóth, É. J. Biol. Inorg. Chem. 2008, 13, 35-46.
(68) Dhingra, K.; Maier, M. E.; Beyerlein, M.; Angelovski, G.; Logothetis, N. K. Chem. Commun. 2008, 3444-3446.
(69) Mishra, A.; Fousková, P.; Angelovski, G.; Balogh, E.; Mishra, A. K.; Logothetis, N. K.; Tóth, É. Inorg. Chem. 2008, 47, 1370-1381.
(70) Hanaoka, K.; Kikuchi, K.; Urano, Y.; Nagano, T. J. Chem. Soc. Perkin Trans. 2001, 1840-1843.
(71) Hanaoka, K.; Kikuchi, K.; Urano, Y.; Narazaki, M.; Yokawa, T.; Sakamoto, S.; Yamaguchi, K.; Nagano, T. Chem. Biol. 2002, 9, 1027-1032.
(72) Trokowski, R.; Ren, J.; Kálmán, F. K.; Sherry, A. D. Angew. Chem., Int. Ed. 2005, 44, 6920-6923.
(73) Major, J. L.; Parigi, G.; Luchinat, C.; Meade, T. J. Proc. Natl. Acad. Sci. USA 2007, 104, 13881-13886.
(74) Zhang, X.; Lovejoy, K. S.; Jasanoff, A.; Lippard, S. J. Proc. Natl. Acad. Sci. USA 2007, 104, 10780-10785.
(75) Major, J. L.; Boiteau, R. M.; Meade, T. J. Inorg. Chem. 2008, 47, 10788-10795.
(76) Hifumi, H.; Tanimoto, A.; Citterio, D.; Komatsu, H.; Suzuki, K. Analyst 2007, 132,1153-1160.
(77) Cooper, T. H.; Mayer, M. J.; Leung, K. H.; Ochrymowycz, L. A.; Rorabacher, D. B. Inorg. Chem. 1992, 31, 3796-3804.
(78) Ambundo, E. A.; Deydier, M.-V.; Grall, A. J.; Aguera-Vega, N.; Dressel, L. T.; Cooper, T. H.; Heeg, M. J.; Ochrymowycz, L. A.; Rorabacher, D. B. Inorg. Chem. 1999, 38, 4233-4242.
(79) Tanaka, M.; Nakamura, M.; Ikeda, T.; Ikeda, K.; Ando, H.; Shibutani, Y.; Yajima, S.; Kimura, K. J. Org. Chem. 2001, 66, 7008-7012.
(80) Glenny, M. W.; van de Water, L. G. A.; Vere, J. M.; Blake, A. J.; Wilson, C.; Driessen, W. L.; Reedijk, J.; Schröder, M. Polyhedron 2006, 25, 599-612.
(81) Konrad, M.; Meyer, F.; Heinze, K.; Zsolnai, L. J. Chem. Soc. Dalton Trans. 1998, 199-206.
(82) Nolan, E. M.; Lippard, S. J. J. Am. Chem. Soc. 2003, 125, 14270-14271.
(83) Forshee, P. B.; Sibert, J. W. Synthesis 2006, 756-758.
(84) Dawson, T. P. J. Am. Chem. Soc. 1933, 55, 2070-2075.
(85) Nolan, E. M.; Lippard, S. J. Inorg. Chem. 2004, 43, 8310-8317.
(86) Demeshko, S.; Leibeling, G.; Maringgele, W.; Meyer, F.; Mennerich, C.; Klauss, H.-H.; Pritzkow, H. Inorg. Chem. 2005, 44, 519-528.
(87) Li, C.; Wong, W.-T. Tetrahedron 2004, 60, 5595-5601.
(88) Dadabhoy, A.; Faulkner, S.; Sammes, P. G. J. Chem. Soc. Perkin Trans. 2002, 348-357.
(89) Prasuhn Jr, D. E.; Yeh, R. M.; Obenaus, A.; Manchester, M.; Finn, M. G. Chem. Commun. 2007, 1269-1271.
(90) Pope, S. J. A.; Laye, R. H. Dalton Trans. 2006, 3108-3113.
(91) Aime, S.; Batsanov, A. S.; Botta, M.; Howard, J. A. K.; Lowe, M. P.; Parker, D. New J. Chem. 1999, 23, 669-670.
(92) Vymazal, J.; Bulte, J. W. M.; Frank, J. A.; Chiro, G. D.; Brooks, R. A. J. Magn. Reson. Imag. 1993, 3, 637-640.
(93) Sarka, L.; Burai, L.; Brucher, E. Chem. Eur. J. 2000, 6, 719-724.
(94) Tweedle, M. F.; Hagan, J. J.; Kumar, K.; Mantha, S.; Chang, C. A. Magn. Reson. Imag. 1991, 9, 409-415.
(95) Job, P. Ann. Chim. (Paris) 1928, 9, 113.
(96) Smith, R. M.; Martell, A. E. Critical Stability Constants; Plenum Press New York, 1989.
(97) Frederickson, C. J.; Koh, J. Y.; Bush, A. I. Nat. Rev. Neurosci. 2005, 6, 449-462.
(98) Chang, C. A.; Francesconi, L. C.; Malley, M. F.; Kumar, K.; Gougoutas, J. Z.; Tweedle, M. F.; Lee, D. W.; Wilson, L. J. Inorg. Chem. 1993, 32, 3501-3508.
(99) Aime, S.; Gianolio, E.; Terreno, E.; Giovenzana, G. B.; Pagliarin, R.; Sisti, M.; Palmisano, G.; Botta, M.; Lowe, M. P.; Parker, D. J. Biol. Inorg. Chem. 2000, 5, 488-497.
(100) Urbanczyk-Pearson, L. M.; Femia, F. J.; Smith, J.; Parigi, G.; Duimstra, J. A.; Eckermann, A. L.; Luchinat, C.; Meade, T. J. Inorg. Chem. 2008, 47, 56-68.
(101) Parker, D. Coord. Chem. Rev. 2000, 205, 109-130.
(102) Bruce, J. I.; Dickins, R. S.; Govenlock, L. J.; Gunnlaugsson, T.; Lopinski, S.; Lowe, M. P.; Parker, D.; Peacock, R. D.; Perry, J. J. B.; Aime, S. J. Am. Chem. Soc 2000, 122, 9674-9684.
(103) Lowe, M. P.; Parker, D. Chem. Commun. 2000, 707-708.
(104) Bretonniére, Y.; Cann, M. J.; Parker, D.; Slater, R. Chem. Commun. 2002, 1930-1931.
(105) Atkinson, P.; Bretonniére, Y.; Parker, D. Chem. Commun. 2004, 438-439.
(106) Parker, D.; Yu, J. Chem. Commun. 2005, 3141-3143.
(107) Murray, B. S.; New, E. J.; Pal, R.; Parker, D. Org. Biomol. Chem. 2008, 6, 2085-2094.
(108) Adrogue, H. J.; Madias, N. E. N. Engl. J. Med. 1998, 338, 26-34.
(109) Lauffer, R. B. Chem. Rev. 1987, 87, 901-927.
(110) Messeri, D.; Lowe, M. P.; Parker, D.; Botta, M. Chem. Commun. 2001, 2742-2743.

(111) Horrocks Jr, W. D.; Sudnick, D. R. Acc. Chem. Res. 1981, 14, 384-392.
(112) Rapisarda, V. A.; Volentini, S. I.; FarÌas, R. N.; Massa, E. M. Anal. Biochem. 2002, 307, 105-109.
(113) Gunnlaugsson, T.; Leonard, J. P.; Senechal, K.; Harte, A. J. Chem. Commun. 2004, 782-783.
(114) Alpoim, M. C.; Urbano, A. M.; Geraldes, C.; Peters, J. A. J. Chem. Soc. Dalton Trans. 1992, 463-467.
(115) Hwang, L.-P.; Freed, J. H. J. Chem. Phys. 1975, 63, 4017-4025.

1. A composition comprising (a) a first chelator chelated to a first metal ion and (b) a second chelator covalently bound to the first chelator, wherein the second chelator is not chelated to a second metal ion.

2. The composition of claim 1 wherein the second chelator forms a coordinate bond with the first metal ion.

3. A composition comprising (a) a first chelator chelated to a first metal ion and (b) a second chelator covalently bound to the first chelator, wherein the second chelator is chelated to a second metal ion.

4. The composition of claim 3 wherein the second chelator does not form a coordinate bond with the first metal ion.

5. The composition of claim 1 wherein the first chelator is a DO3A derivative.

6. The composition of claim 1 wherein the first chelator has the structure 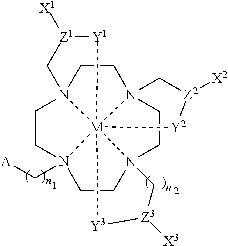
wherein n₁ and n₂ are independently selected from 0, 1, 2, 3, 4, 5 and 6;
Z¹, Z² and Z³ are C;
X¹, X² and X³ are independently selected from ═O, SH, CH₃ and NH₂;
Y¹, Y² and Y³ are independently selected from O and NR¹R²;
wherein R¹ and R² are independently selected from H, substituted or unsubstituted alkyl, substituted or unsubstituted heteroalkyl, substituted or unsubstituted aryl, substituted or unsubstituted heteroaryl;
A is the second chelator; and
M is the first metal ion.

7. The composition of claim 6 wherein Z¹, Z² and Z³ are C; X¹, X² and X³ are ═O and Y¹, Y² and Y³ are O.

8. The composition of claim 6 wherein A is selected from substituted or unsubstituted alkyl, substituted or unsubstituted heteroalkyl, substituted or unsubstituted cycloalkyl, substituted or unsubstituted heterocycloalkyl, substituted or unsubstituted aryl and substituted or unsubstituted heteroaryl.

9. The composition of claim 6 wherein A has the structure -A¹-A²
wherein A¹ is selected from substituted or unsubstituted alkylene; substituted or unsubstituted heteroalkylene; substituted or unsubstituted heterocycloalkylene and substituted or unsubstituted heteroarylene and
A² is selected from substituted or unsubstituted heteroalkyl and substituted or unsubstituted heterocycloalkyl.

10. The composition of claim 9 wherein A¹ has the structure
—R³—R⁴—R⁵—
wherein R³ and R⁵ are independently selected from substituted or unsubstituted alkylene and substituted or unsubstituted heteroalkylene; and
R⁴ is selected from substituted or unsubstituted heterocycloalkylene and substituted or unsubstituted heteroarylene.

11. The composition of claim 10 wherein R³ is unsubstituted alkylene, R⁴ is unsubstituted heteroarylene and R⁵ is unsubstituted alkylene.

12. The composition of claim 9 wherein A¹ has the structure

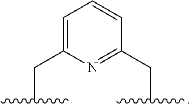

13. The composition of claim 9 wherein A² has the structure —NR⁶R⁷
wherein R⁶ is selected from substituted or unsubstituted alkyl and substituted or unsubstituted heteroalkyl,
R⁷ is substituted or unsubstituted heteroalkyl and
R⁶ and R⁷ are optionally joined to form a ring.

14. The composition of claim 13 wherein at least one of R⁶ and R⁷ has the structure
—(R⁸—R⁹)ₚ—R¹⁰
wherein p is selected from 1 and 2;
R⁸ is substituted or unsubstituted alkylene,
R⁹ is selected from S and O; and
R¹⁰ is selected from H and substituted or unsubstituted alkyl.

15. The composition of claim 9 wherein A² has the structure 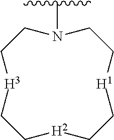
wherein H¹, H² and H³ are independently selected from S and O.

16. The composition of claim 9 wherein A² comprises at least one sulfur atom.

17. The composition of claim 9 wherein A² is selected from 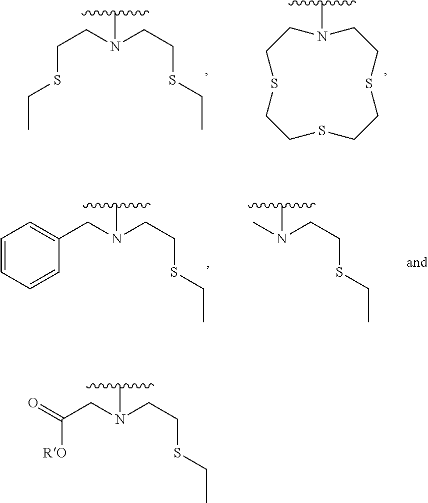
wherein R′ is selected from H and butyl.

18. The composition of claim 1 wherein the first metal ion is an ion of a metal selected from Gd, Tb, Eu, Yb and Dy.

19. The composition of claim 1 wherein the second metal ion is a copper ion.

20. A method of assaying a sample comprising (a) contacting the sample with the composition of claim 1; and (b) measuring an MRI signal produced by the sample.
